(19) United States
(12) Patent Application Publication
(10) Pub. No.: US 2026/0182251 A1
(43) Pub. Date: Jun. 25, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chao-Hung CHU, Keelung City (TW); Yi-Hsien CHANG, Shetou Township (TW); Shih-Fen HUANG, Jhubei (TW)

(21) Appl. No.: 18/990,464

(22) Filed: Dec. 20, 2024

(51) Int. Cl. H10N 30/20; B81B 3/00; B81C 1/00

(52) U.S. Cl. CPC H10N 30/2047; B81B 3/0021; B81C 1/00158; B81B 2207/07

(57) ABSTRACT

A semiconductor device includes routing layers and piezoelectric structures on opposite sides of a substrate. The routing layers and electrodes of the piezoelectric structures are connected by interconnect structures which extend through the substrate between the opposite the sides of the substrate. The arrangement of the routing layers and piezoelectric structures enables the semiconductor devices to be manufactured without and/or with less planarization during fabrication than if the routing layers and piezoelectric structures were formed on the same side of the substrate. Consequently, metal-based routing layers of the semiconductor device (e.g., copper-based and/or aluminum-based routing layers) may be fabricated with passivation layer coverage without causing unwanted current leakage, charge defects, and/or changes in switching charge in the piezoelectric structures, enabling increased reliability and performance of the piezoelectric structures to be achieved relative to if the routing layers and piezoelectric structures were formed on the same side of the substrate.

### BACKGROUND

A piezoelectric device may include a piezoelectric layer deposited between two electrodes. When a voltage is applied between the first electrode and the second electrode, an electrical field is generated by the applied voltage. The electric field causes the piezoelectric layer to stretch and/or compress in a direction that is approximately orthogonal to the surface of the piezoelectric layer. The stretching and/or compression of the piezoelectric layer may be translated into a physical displacement. Such physical displacement can be used to control various kinds of micro-electromechanical systems (MEMS), such as MEMS speakers, MEMS microphones, and/or other MEMS devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A-2X are diagrams of an example implementation of forming a semiconductor device described herein.

FIG. 3 is a diagram of an example semiconductor device described herein.

FIGS. 4A-4L are diagrams of an example implementation of forming a semiconductor device described herein.

FIG. 5 is a diagram of an example implementation of a semiconductor device described herein.

FIG. 6 is a diagram of an example implementation of a semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a planarization process (e.g., a chemical-mechanical planarization (CMP) process) may be performed during fabrication of a piezoelectric device to remove defects and/or uneven areas to produce flat surfaces on which passivation layers can be deposited to achieve sufficient coverage of the passivation layers on metal layers of the piezoelectric device. For example, planarization may be performed to remove pinhole-induced seams and/or defect paths that may have been created during reliability testing. In more detail, pinhole-induced seams may be used during reliability testing to create paths for acids that test for corrosion resistance of the metal layers. However, when the metal layers (which may include copper-based and/or aluminum-based routing layers connected to electrodes of piezoelectric devices) are subjected to the mechanical stress caused by the planarization process, an electric field may build up in the metal layers. The electric field can cause the piezoelectric device to exhibit current leakage, charge defects, and/or changes in switching charge, thereby reducing the reliability and performance of the piezoelectric device.

Instead of the planarization process, thick planarization layers may be used to cover defects that would otherwise be removed by the planarization process. However, excess passivation layer coverage may lead to wafer warpage and/or poor actuating performance of actuators of the piezoelectric device.

Some implementations described herein provide semiconductor devices in which routing layers and piezoelectric structures are fabricated on opposite sides (e.g., a front side and a back side) of a substrate. The routing layers and electrodes of the piezoelectric structures are connected by interconnect structures which extend through the substrate between the opposite the sides of the substrate. The arrangement of the routing layers and piezoelectric structures enables the semiconductor devices to be manufactured without and/or with less planarization during fabrication than if the routing layers and piezoelectric structures were formed on the same side of the substrate. In addition, even if some planarization is performed on the routing layers during fabrication, the separation of the routing layers and piezoelectric structures by being on opposite sides of the substrate avoids and/or minimizes the effects that a built-up electric field in the routing layers may otherwise have on the structures. As a result, metal-based routing layers of the semiconductor device (e.g., copper-based and/or aluminum-based routing layers) may be fabricated with passivation layer coverage without causing unwanted current leakage, charge defects, and/or changes in switching charge in the piezoelectric structures, enabling increased reliability and performance of the piezoelectric structures to be achieved relative to if the routing layers and piezoelectric structures were formed on the same side of the substrate.

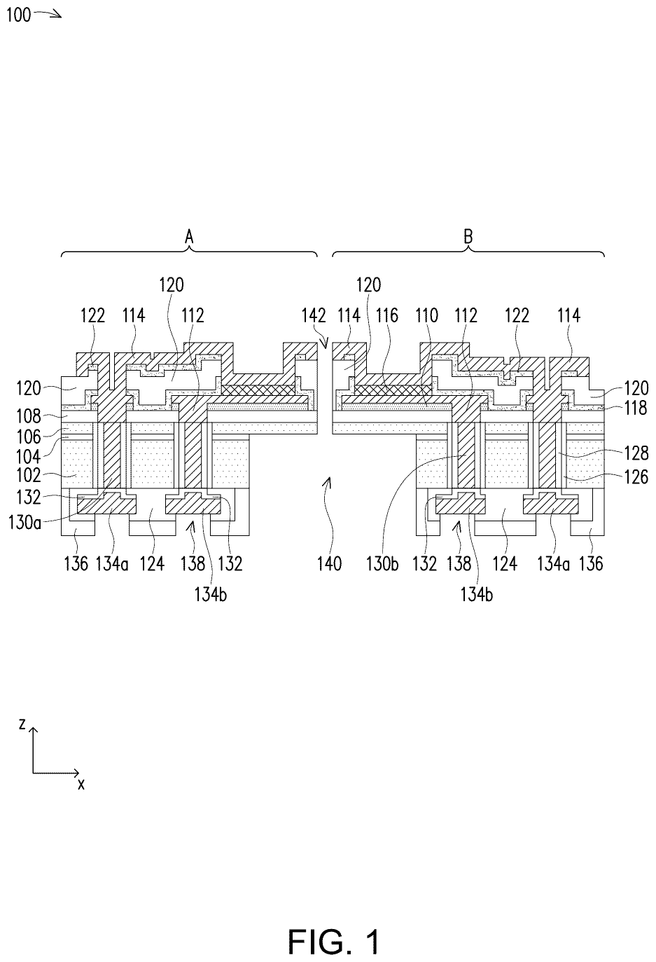

FIG. 1 is a diagram of an example semiconductor device 100 described herein. The semiconductor device 100 may be a micro-electromechanical systems (MEMS) device, such as a MEMS actuator, a MEMS sensor, or a MEMS harvester, among other examples. As shown in FIG. 1, the semiconductor device 100 may include a silicon-on-insulator (SOI) substrate including a first semiconductor layer 102, an insulator layer 104, and a second semiconductor layer 106. The first semiconductor layer 102 and the second semiconductor layer 106 may include silicon, a material including silicon, a III-V compound semiconductor material such as gallium arsenide (GaAs), germanium (Ge), silicon germanium (SiGe), or another type of semiconductor material. The insulator layer 104 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. The semiconductor device 100 may be cut or diced from a semiconductor wafer after or as a part of manufacturing of the semiconductor device 100. The semiconductor wafer may be a circular wafer. The SOI substrate may alternatively be any square, rectangular, curved, or otherwise non-circular workpiece, such as a polygonal substrate.

Alternatively, instead of an SOI substrate, the semiconductor device 100 may use a silicon (Si) substrate, a substrate formed of a material including silicon, a III-V compound semiconductor material substrate such as gallium arsenide (GaAs), a germanium substrate (Ge), a silicon germanium (SiGe) substrate, or another type of semiconductor substrate.

The semiconductor device 100 may include a base insulator layer 108 on a top surface of the second semiconductor layer 106, and an insulator adhesion layer 110 on a top surface of the base insulator layer 108. The base insulator layer 108 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. The insulator adhesion layer 110 may include titanium oxide (TiOₓ such as TiO₂), zinc oxide (ZnO), aluminum oxide (AlₓO_{y} such as Al₂O₃), and/or chromium oxide (CrₓO_{y} such as Cr₂O₃). A thickness of the base insulator layer 108 may be included in a range of approximately 300 nanometers to approximately 2000 nanometers, and a thickness of the insulator adhesion layer 110 may be included in a range of approximately 20 nanometers to approximately 200 nanometers. However, other values and ranges are within the scope of the present disclosure.

The semiconductor device 100 may include a plurality of piezoelectric structures, each piezoelectric structure including a first electrode 112 (e.g., bottom electrode), a second electrode 114 (e.g., top electrode), and a piezoelectric layer 116 between a portion of the first electrode 112 and a portion of the second electrode 114. A base portion of the first electrode 112 and a base portion of the second electrode 114 for each piezoelectric structure may be disposed through the base insulator layer 108 and the insulator adhesion layer 110 into the second semiconductor layer 106. The portion of the first electrode 112 under the piezoelectric layer 116 may be over and/or on the insulator adhesion layer 110, and the insulator adhesion layer 110 may promote adhesion of the first electrode 112 to the base insulator layer 108. Additional parts of the first electrode 112 and of the second electrode 114 may extend laterally from sides of the base portions of the first electrode 112 and of the second electrode 114 over and/or onto the insulator adhesion layer 110.

The first electrode 112 and the second electrode 114 may each include one or more electrically conductive materials. In some implementations, the first electrode 112 and the second electrode 114 may include a chemically inert electrically conductive material such as a chemically inert metal and/or a chemically inert metal compound. As used herein, “chemically inert” is to be broadly construed to refer to, for example, a substance that is not chemically reactive or does not react under certain circumstances and/or in certain substances.

Some examples of chemically inert metals that can be used for the first electrode 112 and the second electrode 114 include platinum (Pt), molybdenum (Mo), and/or iridium (Ir), among other examples. Examples of chemically inert metal compounds that can be used for the first electrode 112 and the second electrode 114 include lanthanum nickel oxide (LNO) (LaNiOₓ such as LaNiO₃) and/or ruthenium oxide (RuOₓ such as RuO₂).

The piezoelectric layer 116 may be included over and/or on a top surface of the first electrode 112, and under and/or on a bottom surface of second electrode 114. The piezoelectric layer 116 may include lead zirconate titanate (PZT), lithium tantalate (LT), lead magnesium niobate (PMN), sodium potassium niobate (KNN), lead meta niobate (LMN), and/or another piezoelectric (e.g., piezo-ceramic) material. In some implementations, a thickness of the piezoelectric layer 116 may be included in a range of approximately 0.1 micrometers to approximately 10 micrometers. However, other values for the range are within the scope of the present disclosure.

A stack of a first adhesion layer 118, a passivation layer 120, and a second adhesion layer 122 is disposed between parts of the first electrode 112 and of the second electrode 114. In addition, some portions of the first adhesion layer 118 are over and/or on the base insulator layer 108 and/or the insulator adhesion layer 110. The first adhesion layer 118 and the second adhesion layer 122 may include aluminum oxide (AlₓO_{y} such as Al₂O₃), titanium oxide (TiOₓ such as TiO₂), zirconium oxide (ZrOₓ such as ZrO₂), ruthenium oxide (RuOₓ such as RuO₂), zinc oxide (ZnO), and/or chromium oxide (CrₓO_{y} such as Cr₂O₃). The passivation layer 120 may include a dielectric material such as a silicon nitride (SiₓN_{y}), an aluminum nitride (AlN), a hafnium oxide (HfOₓ such as HfO₂), a zinc oxide (ZnO), and/or a silicon carbide (SiC).

In some implementations, the base portion of the second electrode 114 is physically connected to other portions of the second electrode 114 through a break in the stack of the first adhesion layer 118, the passivation layer 120, and the second adhesion layer 122. In some implementations, a thickness of each of the first adhesion layer 118 and the second adhesion layer 122 may be included in a range of approximately 20 nanometers to approximately 500 nanometers. In some implementations, a thickness of the passivation layer 120 may be included in a range of approximately 300 nanometers to approximately 1000 nanometers. However, other values for the ranges are within the scope of the present disclosure.

A bottom insulator layer 124 is on a bottom surface of the first semiconductor layer 102. The bottom insulator layer 124 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. As referred to herein, the bottom insulator layer 124 and components in and/or under the bottom insulator layer 124 are on a first side (e.g., a bottom side) of the semiconductor device 100, the SOI substrate, or first semiconductor layer 102. As referred to herein, the base insulator layer 108 and components in and/or over the base insulator layer 108 are on a second side (e.g., a top side) of the semiconductor device 100, the SOI substrate, or first semiconductor layer 102. The second side (e.g., top side) is opposite the first side (e.g., bottom side) in the z-direction.

The semiconductor device 100 may include a plurality of conductive structures disposed through the first semiconductor layer 102, the insulator layer 104, and the second semiconductor layer 106. Each of the conductive structures is surrounded by a liner insulator layer 126, and includes a barrier layer 128 and an interconnect fill layer 130. Each combination of a barrier layer and an interconnect fill layer 130 forms an interconnect structure (e.g., a via, a conductive pillar, a through silicon via (TSV), a trench, and/or another type of interconnect structure) through the first semiconductor layer 102, the insulator layer 104, and the second semiconductor layer 106. In some implementations, the liner insulator layer 126 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. In some implementations, a thickness of the liner insulator layer 126 may be included in a range of approximately 300 nanometers to approximately 2000 nanometers. However, other values for the range are within the scope of the present disclosure. In some implementations, the barrier layer 128 may include tantalum nitride (TaN), tungsten nitride (WN), ruthenium nitride (RuNₓ), and/or titanium nitride (TiN), among other examples. In some implementations, the interconnect fill layer 130 may include copper (Cu), tungsten (W), an aluminum-copper alloy (AlCu), gold (Au) and/or cobalt (Co), among other examples.

Respective ones of a plurality of conductive adhesion layers 132 and respective ones of a plurality of conductive (e.g., metal) routing layers 134 are in contact with a first end of an interconnect structure at the first side of the semiconductor device 100, the SOI substrate, or the first semiconductor layer 102. A base portion of a first electrode 112 or a base portion of a second electrode 114 is in contact with a second end of an interconnect structure at the second side of the semiconductor device 100, the SOI substrate, or the first semiconductor layer 102. In some implementations, a conductive adhesion layer 132 may include titanium nitride (TiN), tantalum nitride (TaN), ruthenium nitride (RuNₓ), ruthenium oxide (RuOₓ such as RuO₂), tungsten nitride (WN), chromium nitride (CrN), and/or molybdenum nitride (MoN), among other examples, and the conductive routing layer 134 may include copper (Cu), aluminum-copper alloy (AlCu), aluminum (Al), tungsten (W), silver (Ag) and/or cobalt (Co). In some implementations, a thickness of a conductive adhesion layer 132 may be included in a range of approximately 300 angstroms to approximately 3000 angstroms, and a thickness of a conductive routing layer 134 may be included in a range of approximately 100 nanometers to approximately 4000 nanometers. However, other values for the ranges are within the scope of the present disclosure. The conductive routing layers 134 may each include a conductive trace, a trench, and/or another type of metallization layer.

As shown in FIG. 1, the conductive fill layers 130 and the conductive routing layers 134 designated 130a and 134a correspond to interconnect structures in contact with the second electrode 114, and the conductive fill layers 130 and the conductive routing layers 134 designated 130b and 134b correspond to interconnect structures in contact with the first electrode 112. An interconnect structure that includes a barrier layer 128 and a conductive fill layer 130a connects a bottom portion of a second electrode 114 on a second side of the semiconductor device 100, the SOI substrate, or the first semiconductor layer 102 to a conductive routing layer 134a on a first side of the semiconductor device 100, the SOI substrate, or the first semiconductor layer 102. An interconnect structure that includes a barrier layer 128 and a conductive fill layer 130b connects a bottom portion of a first electrode 112 on a second side of the semiconductor device 100, the SOI substrate, or the first semiconductor layer 102 to a conductive routing layer 134b on a first side of the semiconductor device 100, the SOI substrate, or the first semiconductor layer 102.

The conductive adhesion layers 132 and the conductive routing layers 134 are in the bottom insulator layer 124, and portions of respective ones of the conductive adhesion layers 132 are in physical contact with respective ones of the interconnect structures including barrier layers 128 and an interconnect fill layer 130. A passivation layer 136 is formed under the bottom insulator layer 124, and includes openings 138 exposing portions of respective ones of the conductive routing layers 134. The passivation layer 136 may include a dielectric material such as a silicon nitride (SiₓN_{y}), an aluminum nitride (AlN), a hafnium oxide (HfOₓ such as HfO₂), a zinc oxide (ZnO), and/or a silicon carbide (SiC). In some implementations, a thickness of the passivation layer 136 may be included in a range of approximately 300 nanometers to approximately 1000 nanometers. However, other values for the range are within the scope of the present disclosure.

As shown in FIG. 1, the semiconductor device 100 includes a first cavity 140 (e.g., airgap) between portions of the SOI substrate including a first set of interconnect structures and a first piezoelectric structure in a left section A of the semiconductor device 100, and a second set of interconnect structures and a second piezoelectric structure in a right section B of the semiconductor device 100. The left section A and the right section B are separated by a second cavity 142 (e.g., airgap). The first piezoelectric structure includes a first electrode 112, a second electrode 114, and a piezoelectric layer 116 in the left section A to the left of the second cavity 142 (e.g., in the x-direction), where a portion of the first piezoelectric structure is cantilevered over part of the first cavity 140. The second piezoelectric structure includes a first electrode 112, a second electrode 114, and a piezoelectric layer 116 in the right section B to the right of the second cavity 142 (e.g., in the x-direction), where a portion of the second piezoelectric structure is opposite the portion of the first piezoelectric structure and is cantilevered over part of the first cavity 140. The first piezoelectric structure includes a bottom portion of a first electrode 112 and a bottom portion of a second electrode 114 in the left section A, which are laterally adjacent to each other in the x-direction.

The first set of interconnect structures in the left section A include a first interconnect structure (including a first interconnect fill layer 130a and barrier layers 128) extending between the bottom portion of the second electrode 114 of the first piezoelectric structure and a conductive routing layer 134a, and a second interconnect structure (including a second interconnect fill layer 130b and barrier layers 128) extending between the bottom portion of the first electrode 112 of the first piezoelectric structure and a conductive routing layer 134b. The first and second interconnect structures of the first set of interconnect structures are laterally adjacent to each other in the x-direction. The second set of interconnect structures in the right section B include a first interconnect structure (including a first interconnect fill layer 130a and barrier layers 128) extending between the bottom portion of the second electrode 114 of the second piezoelectric structure and a conductive routing layer 134a, and a second interconnect structure (including a second interconnect fill layer 130b and barrier layers 128) extending between the bottom portion of the first electrode 112 of the second piezoelectric structure and a conductive routing layer 134b. The first and second interconnect structures of the second set of interconnect structures are laterally adjacent to each other in the x-direction. The first electrodes 112 and the second electrodes may be electrically coupled and/or physically coupled to the interconnect structures, and the interconnect structures may be electrically coupled and/or physically coupled to the conductive routing layers 134.

In some implementations, due to its cantilevered arrangement, the piezoelectric layer 116 in the left section A and/or in the right section B selectively vibrates to generate a sound signal or vibrates based on reception of a sound signal. In more detail, input voltages may be applied to the first electrode 112 and the second electrode 114 through the conductive routing layers 134 and the interconnect structures to generate a voltage across the piezoelectric layer 116, which results in compressive and/or tensile stress on the piezoelectric layer 116, causing the piezoelectric layer 116 to vibrate and generate a sound signal (e.g., for a speaker). Alternatively, a received sound signal causes vibration of the piezoelectric layer 116. The resulting compressive and/or tensile stress on the piezoelectric layer 116, caused by the vibration, generates a voltage across the piezoelectric layer 116, which is received as output voltages by the first electrode 112 and the second electrode 114. The output voltages are transmitted from the first electrode 112 and the second electrode 114 to an appropriate device (e.g., sensor or harvester) through the interconnect structures and the conductive routing layers 134.

As indicated above, FIG. 1 is provided as an example. Other examples may differ from what is described with regard to FIG. 1.

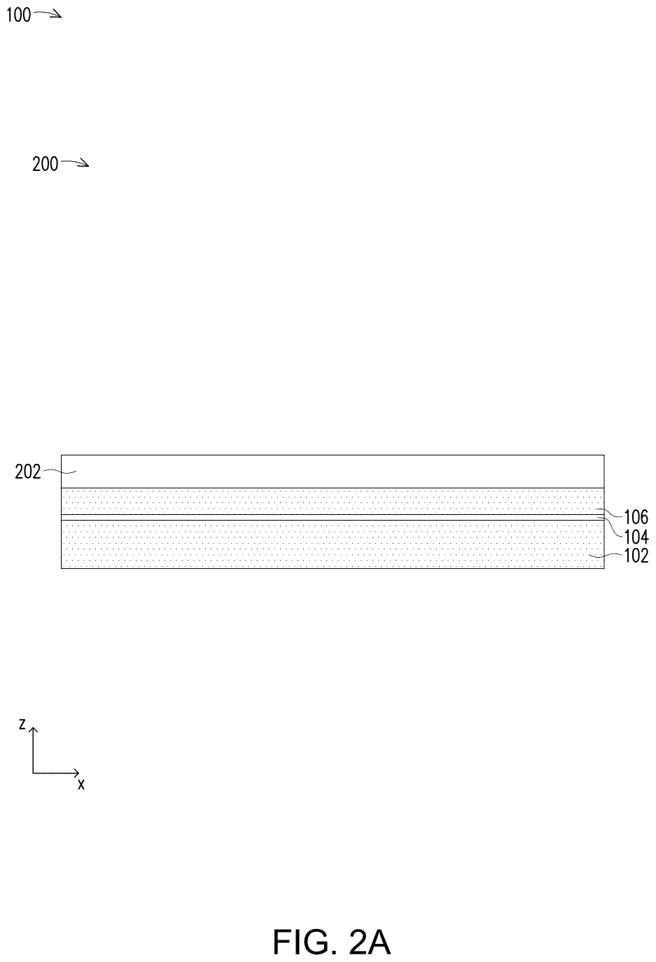

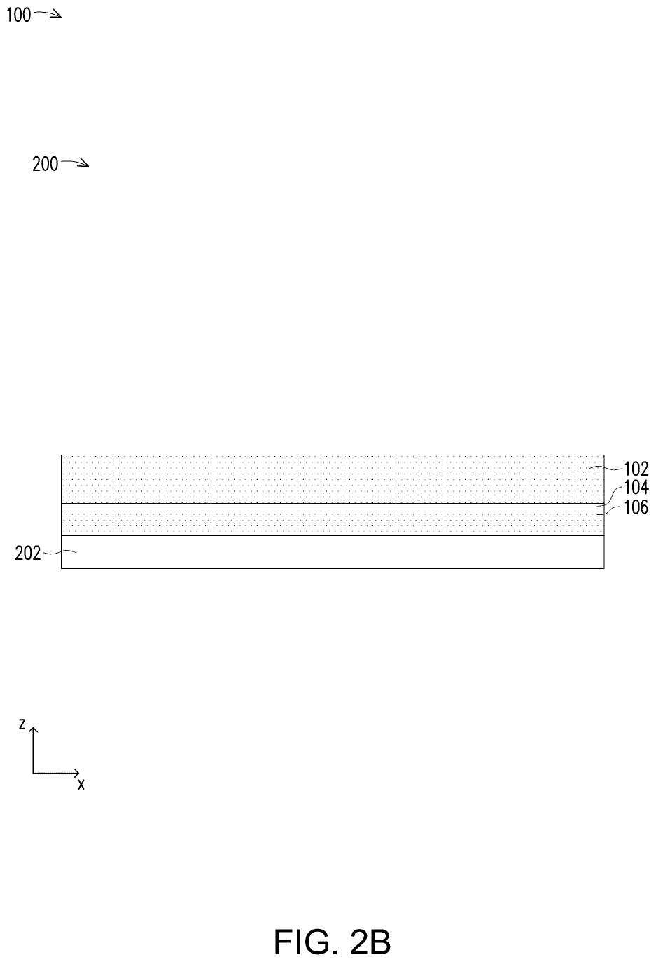

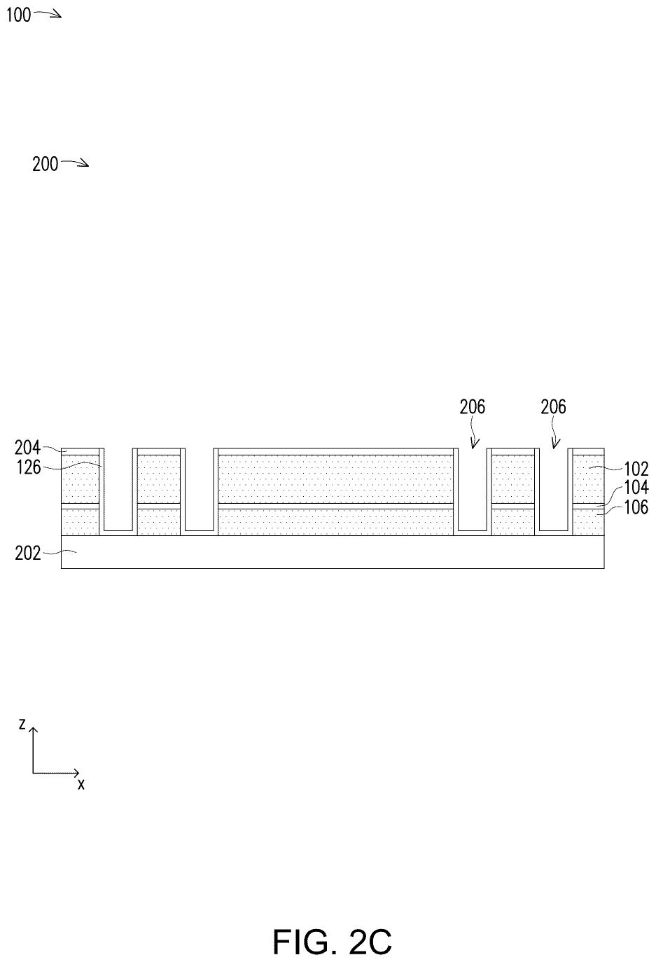

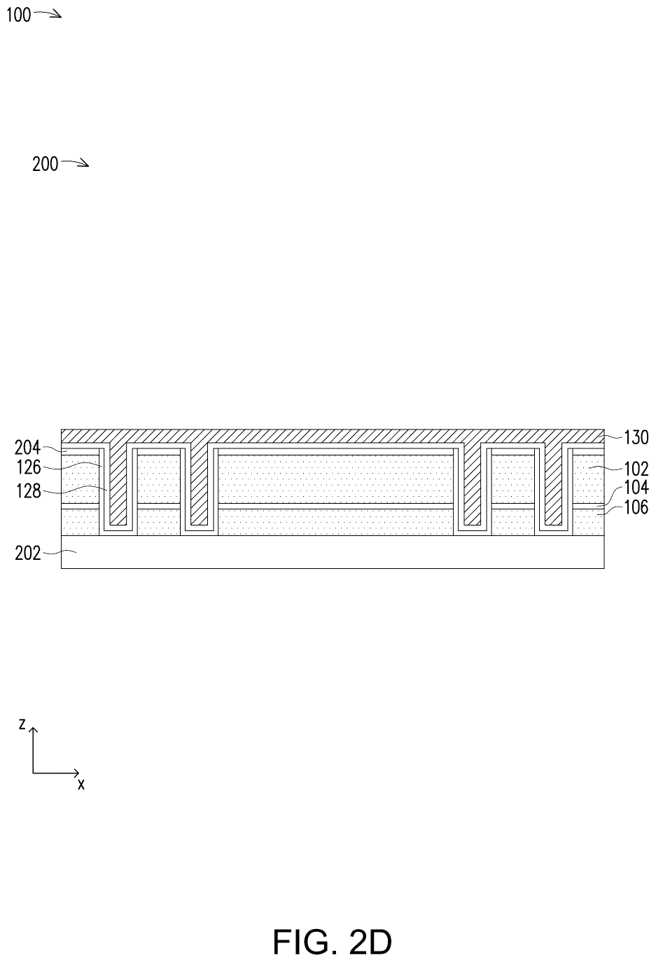

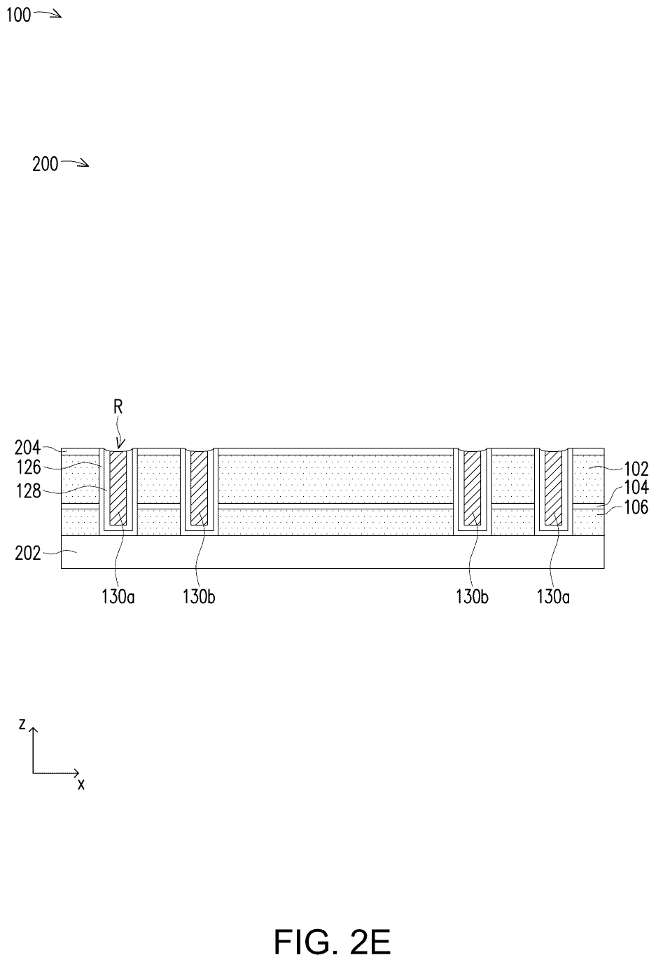

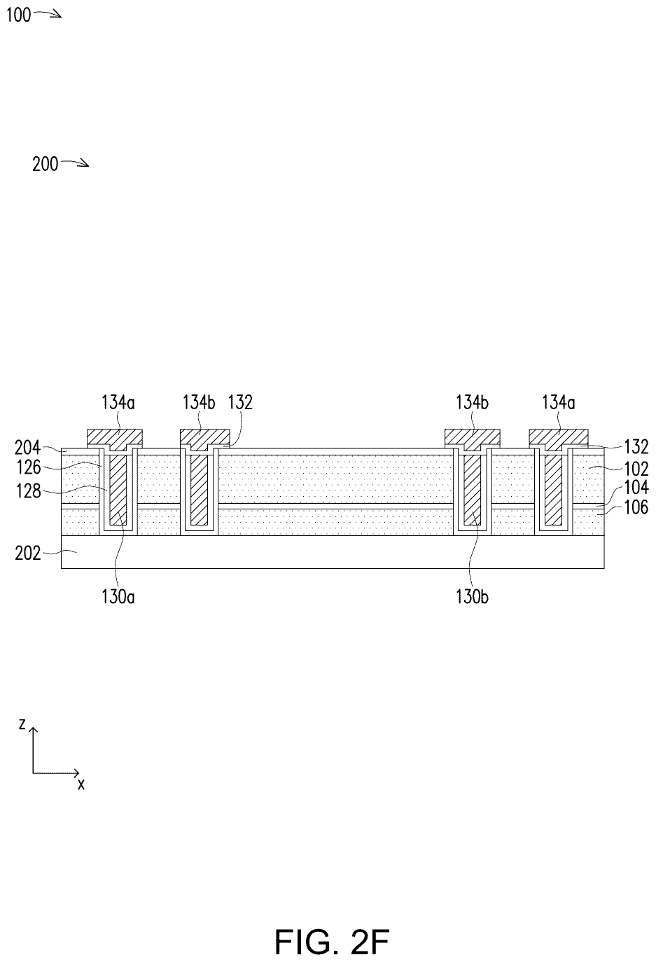

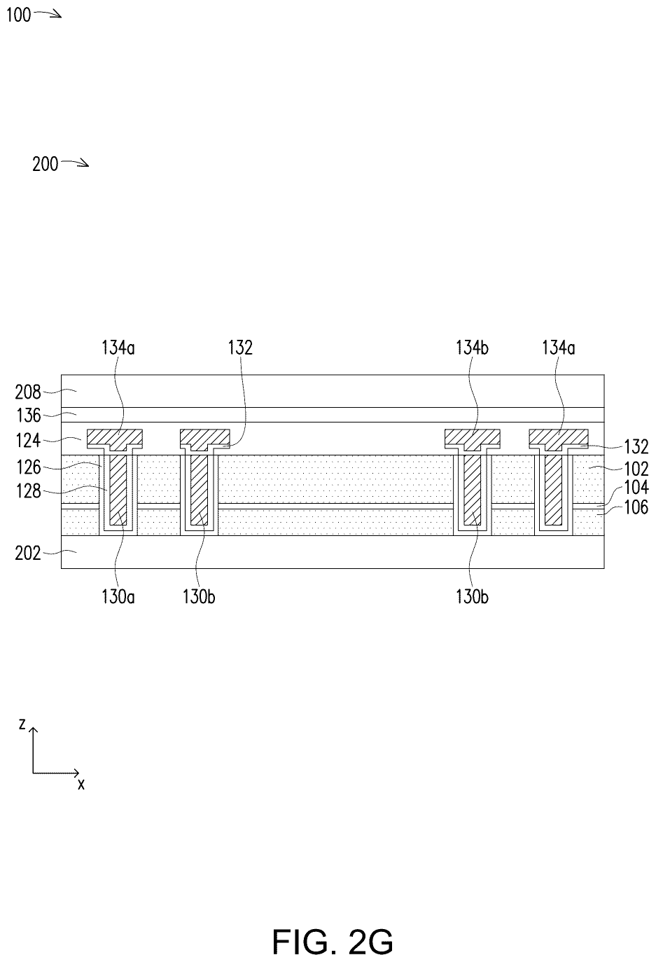

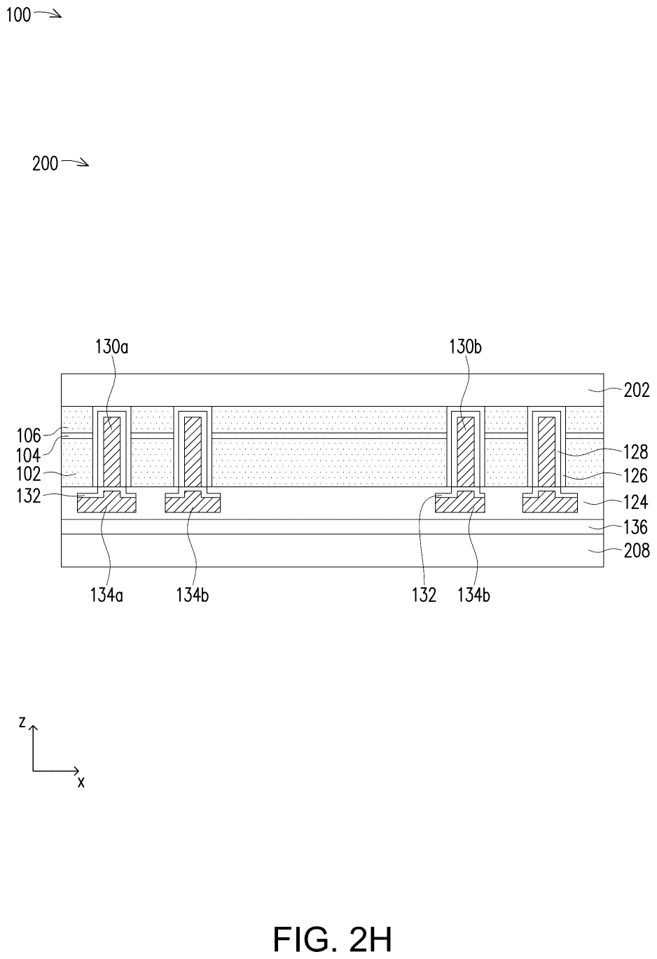

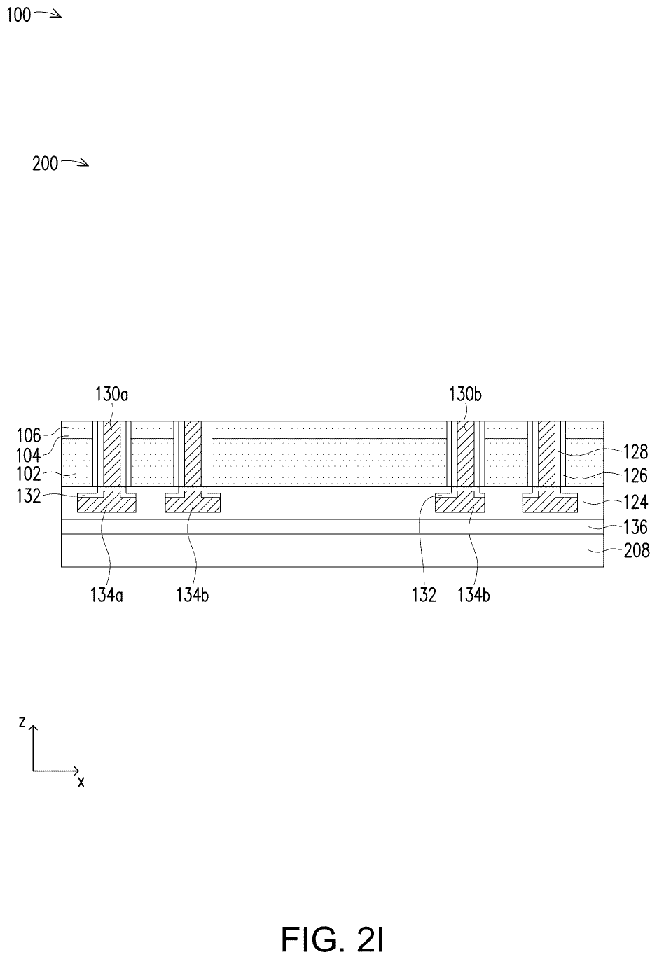

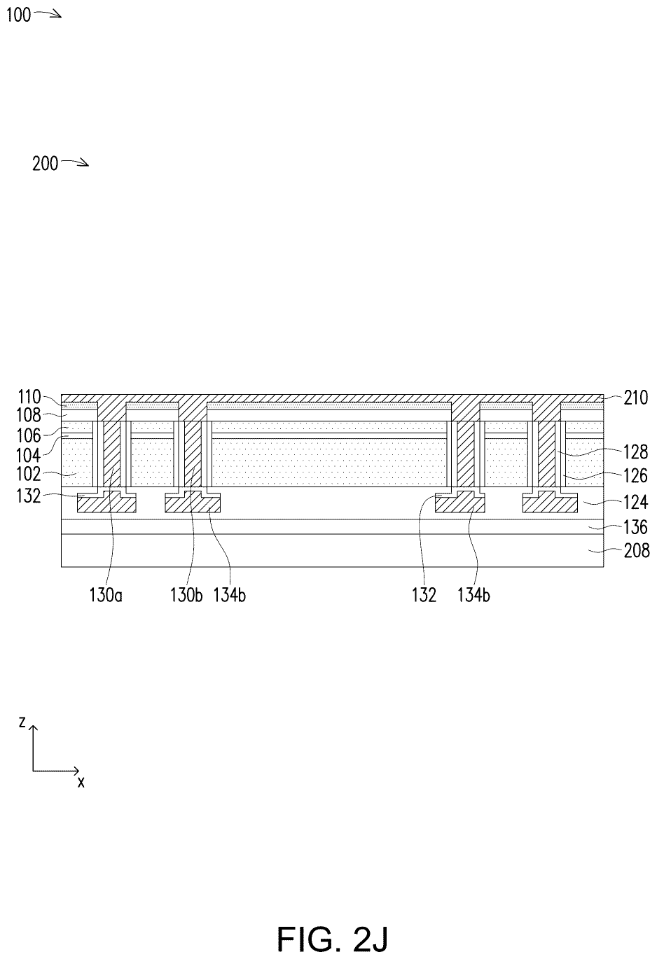

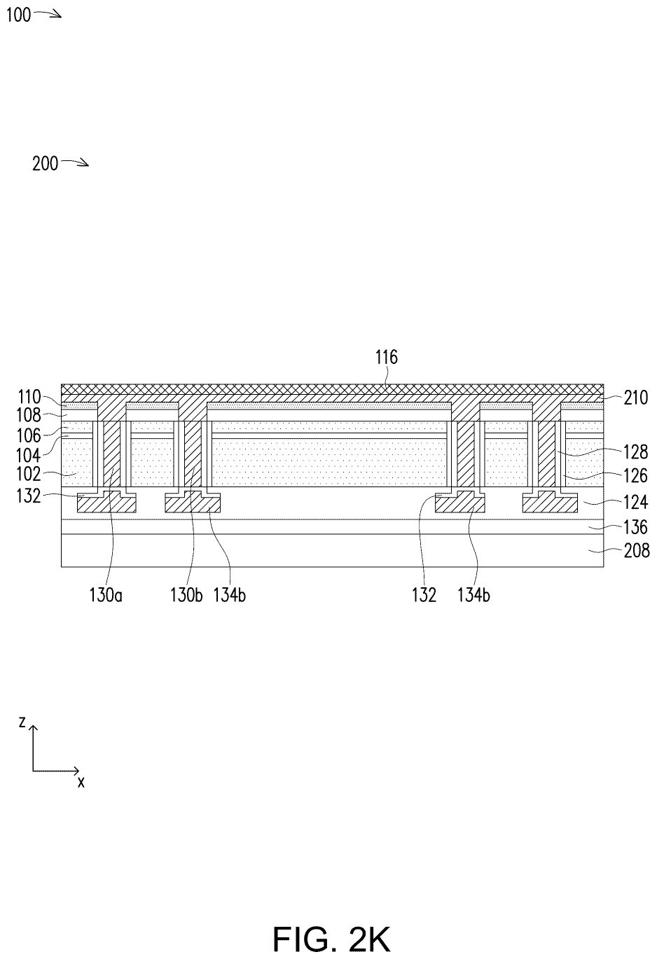

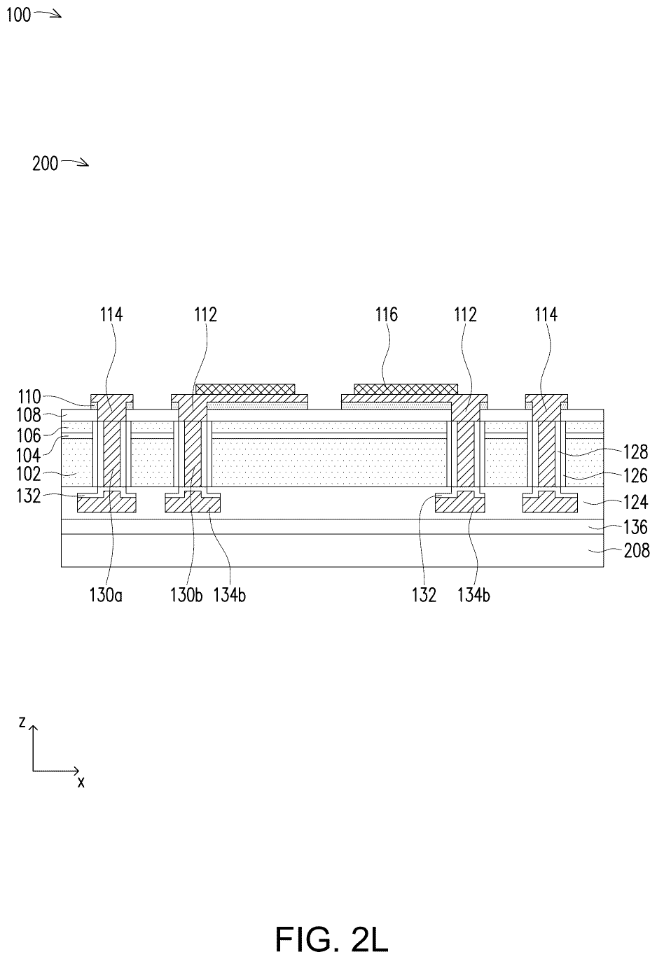

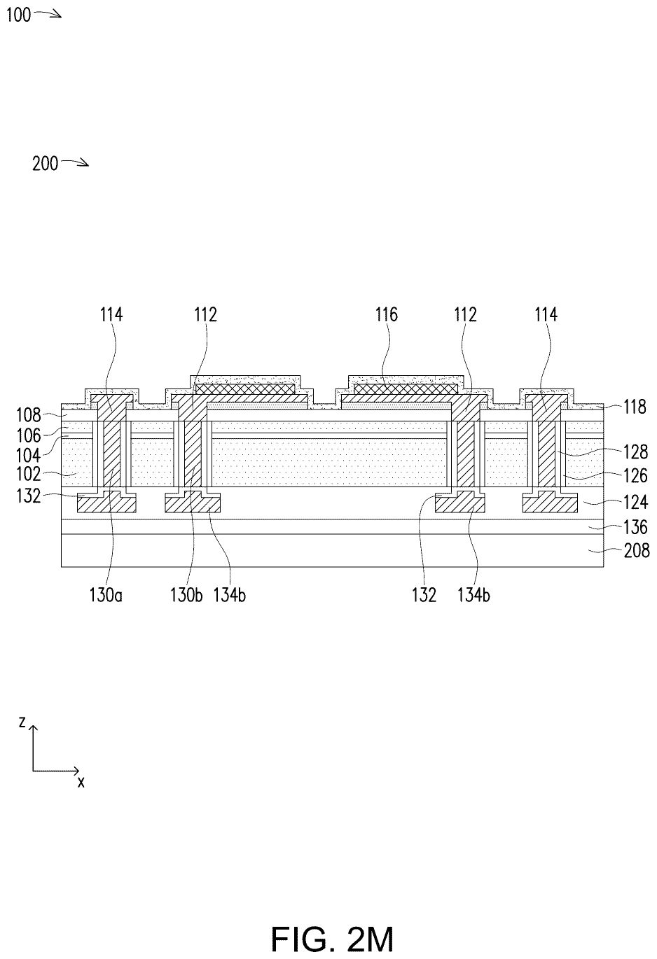

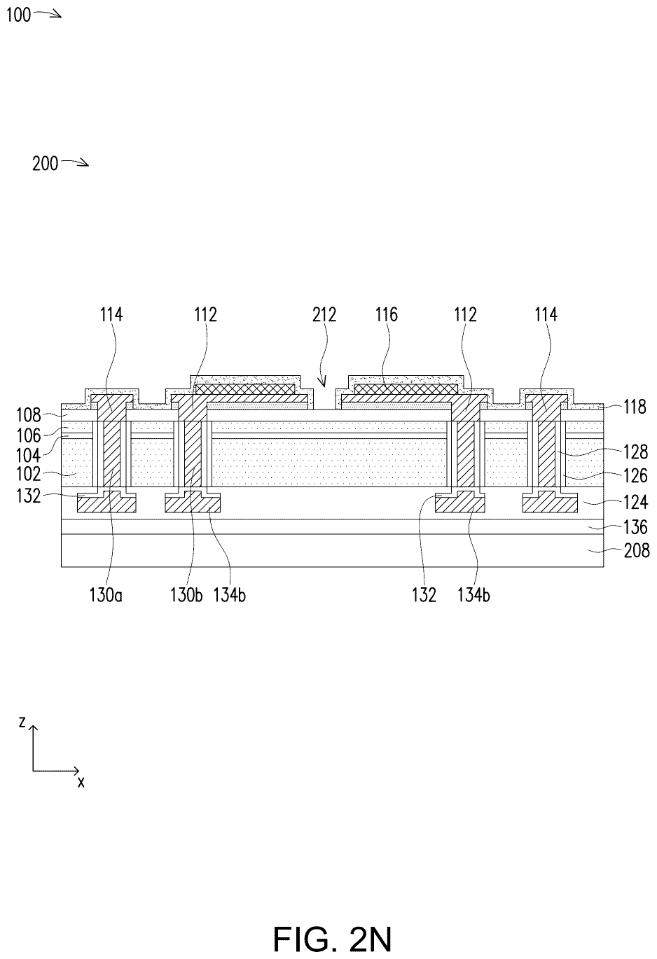

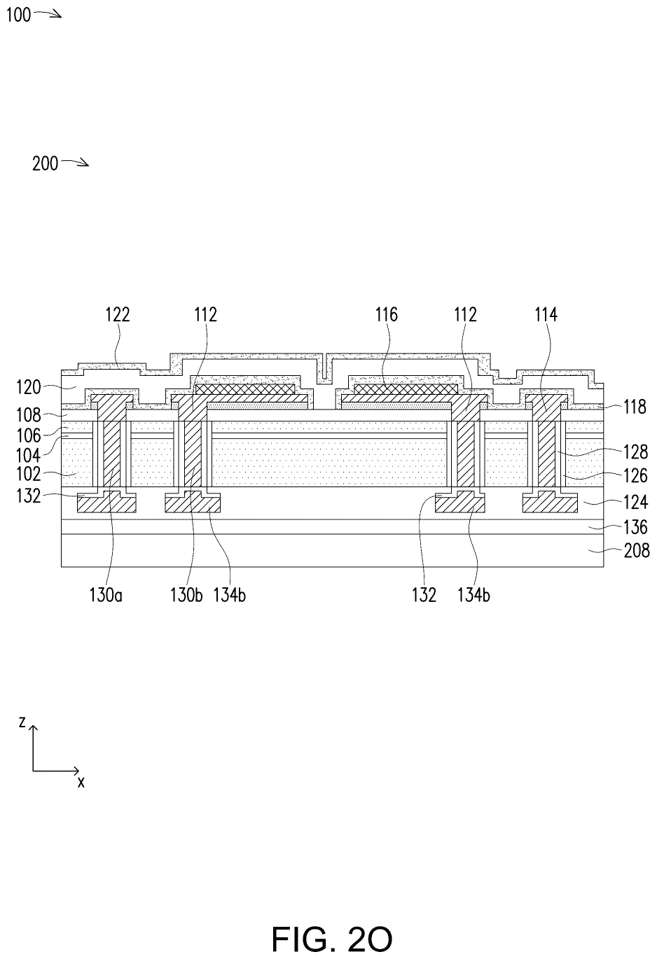

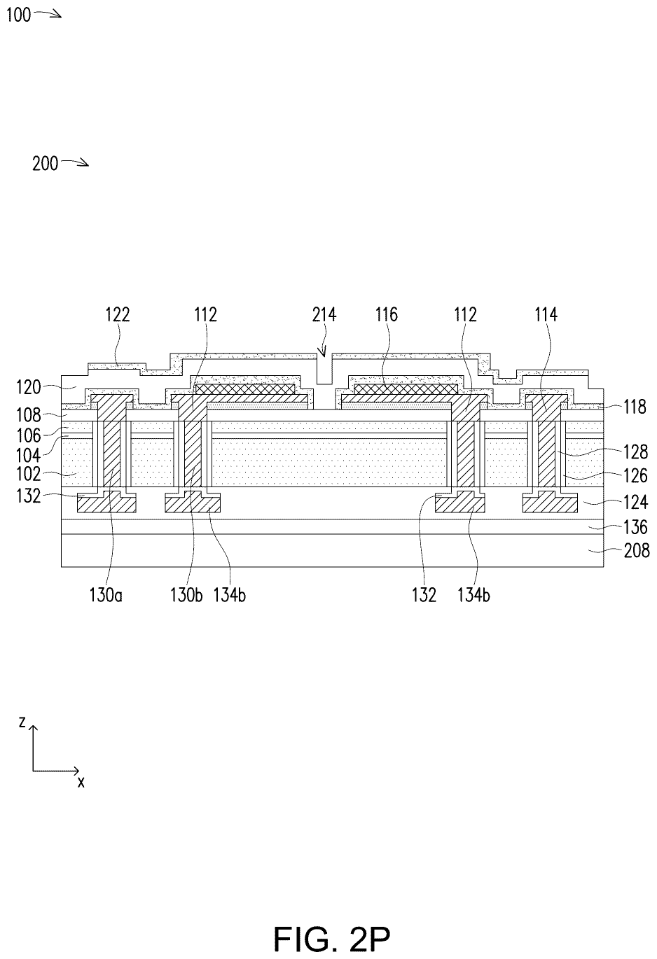

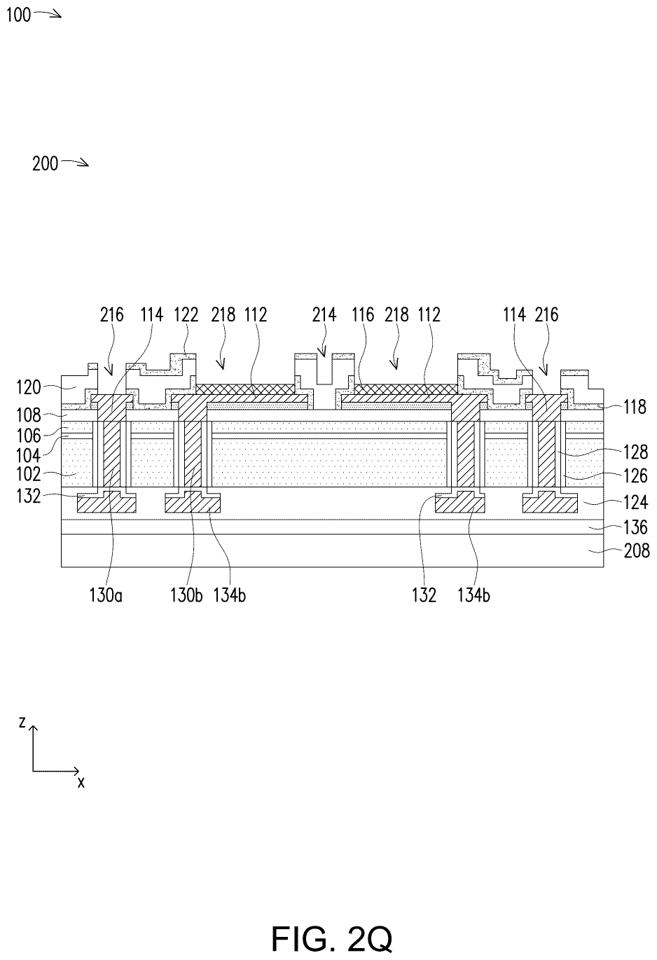

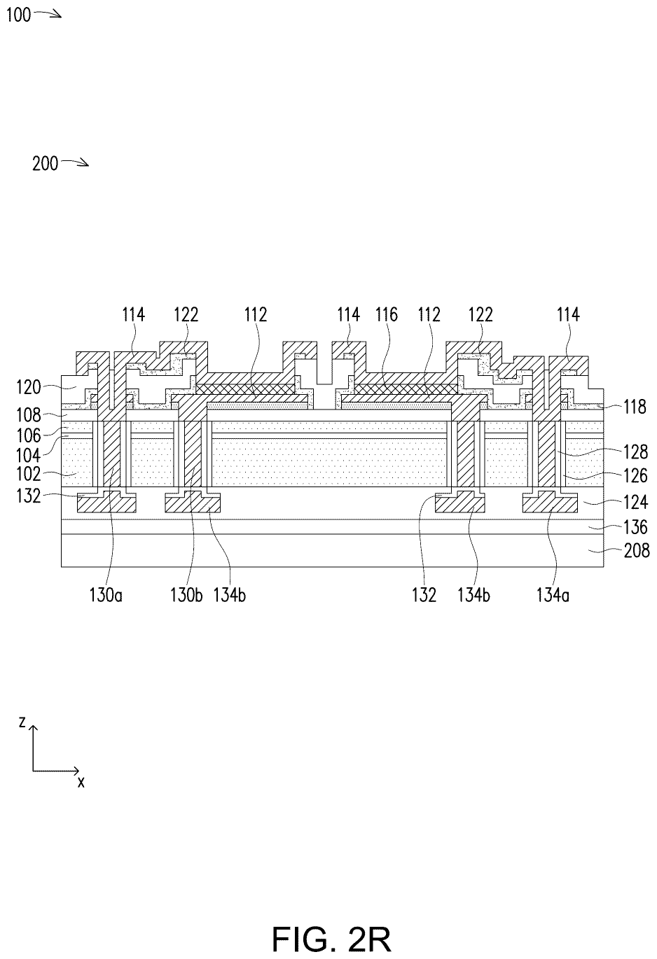

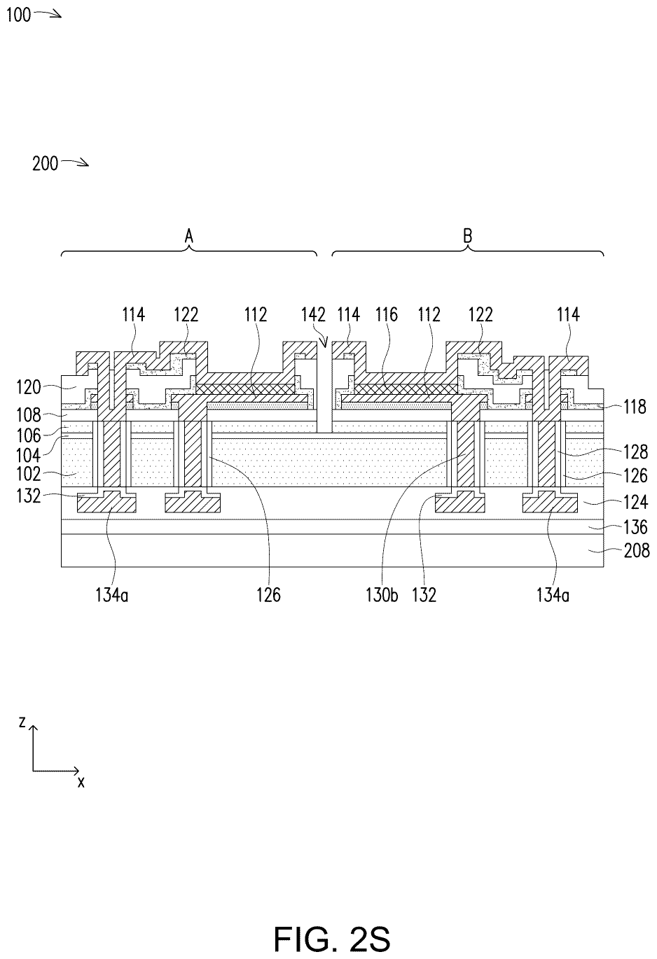

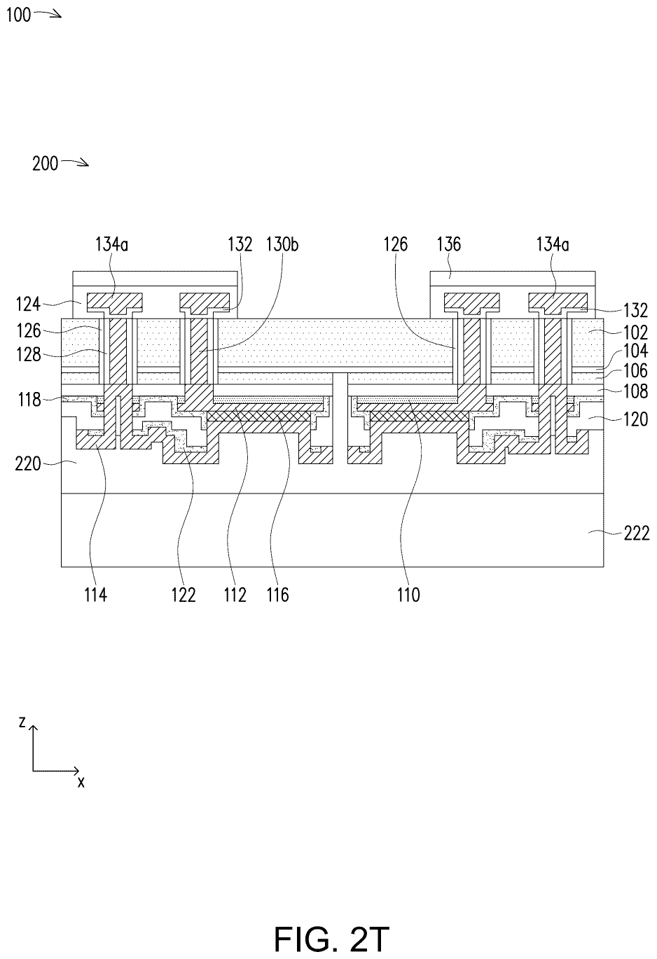

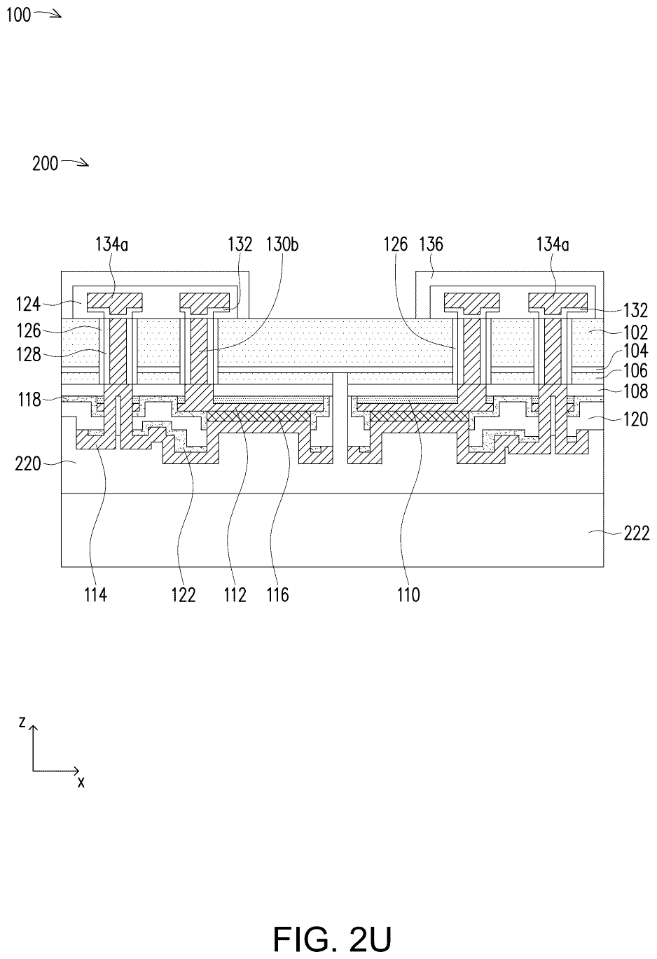

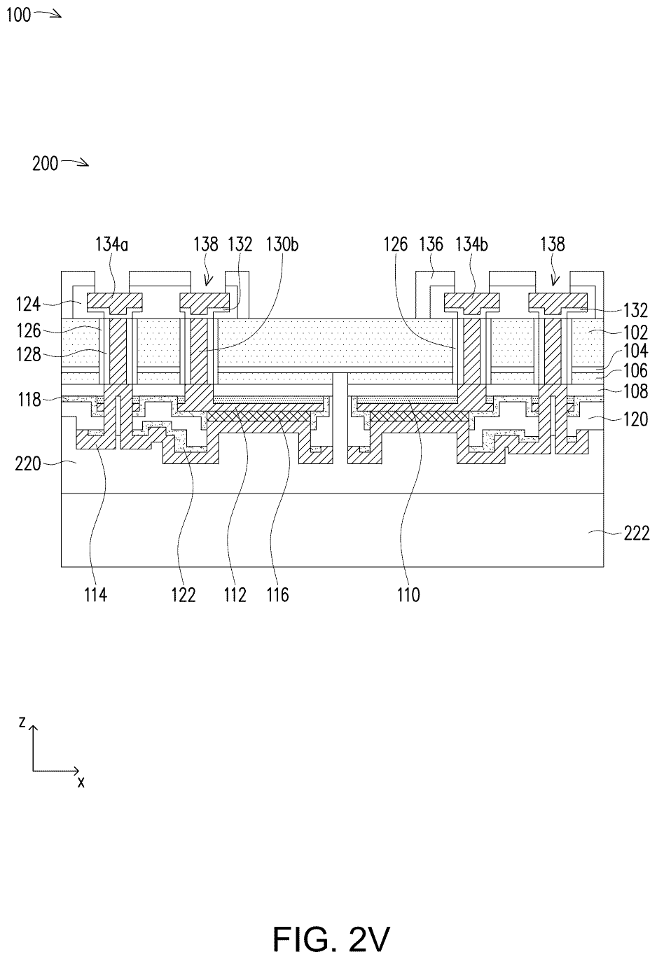

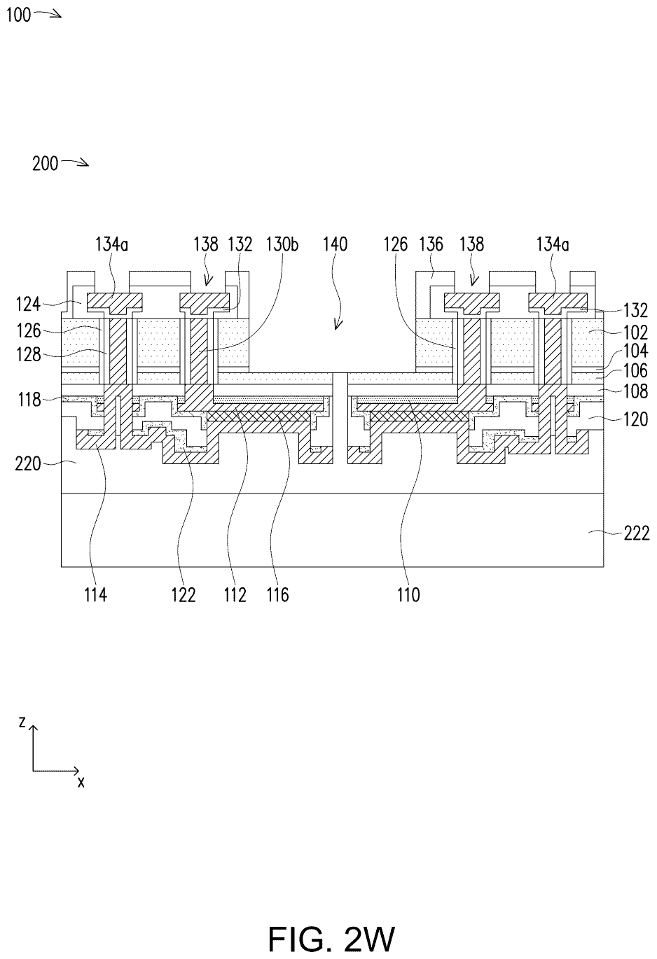

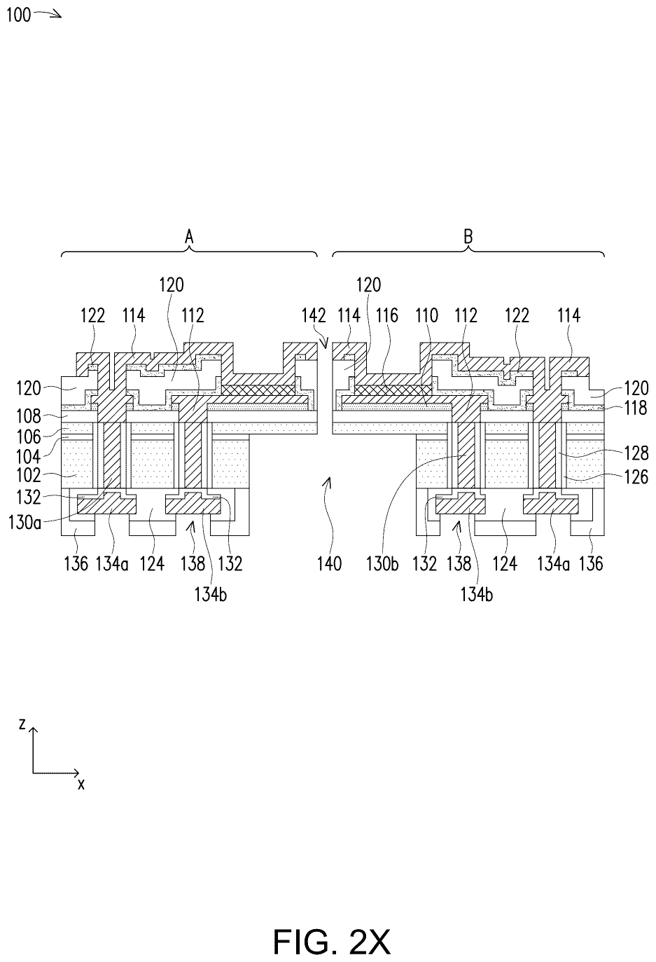

FIGS. 2A-2X are diagrams of an example implementation 200 of forming a semiconductor device 100 described herein. In some implementations, one or more of the semiconductor processing operations described in connection with FIGS. 2A-2X may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the SOI substrate including the first semiconductor layer 102, the insulator layer 104 and the second semiconductor layer 106 is provided. The SOI substrate may be provided in the form of a semiconductor wafer such as an SOI wafer, and/or another type of semiconductor work piece. The semiconductor device 100 may be formed on the semiconductor wafer with other semiconductor devices. A deposition tool may be used to deposit a sacrificial insulator layer 202 on the second semiconductor layer 106 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical-mechanical planarization (CMP) operation to planarize the sacrificial insulator layer 202 after the sacrificial insulator layer 202 is deposited. In some implementations, the sacrificial insulator layer 202 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. In some implementations, a thickness of the sacrificial insulator layer 202 may be included in a range of approximately 1500 nanometers to approximately 3000 nanometers. However, other values for the range are within the scope of the present disclosure.

As shown in FIG. 2B, following deposition of the sacrificial insulator layer 202, the resulting structure is “flipped” (e.g., rotated 180 degrees) using a wafer/die transport tool so that the first semiconductor layer 102 is at a top of the structure instead of a bottom of the structure in the z-direction, and the sacrificial insulator layer 202 is at a bottom of the structure instead of a top of the structure in the z-direction. The first semiconductor layer 102 may be attached to a carrier wafer (not shown), which can be attached to the wafer/die transport tool to perform the rotation. The carrier wafer may be removed after the rotation is performed.

Following the flipping process, a portion of the first semiconductor layer 102 is removed in a grinding process to thin the first semiconductor layer 102 (e.g., to reduce the thickness of the first semiconductor layer 102). The first semiconductor layer 102 may be thinned to reduce the processing time and/or etchant consumption of an etch operation to remove portions of the first semiconductor layer 102. A planarization tool (e.g., a grinding tool) may perform a wafer grinding operation to mechanically grind silicon material away from the first semiconductor layer 102. As a result of the wafer grinding operation, a remaining thickness of the first semiconductor layer 102 is included in the range of approximately 200 micrometers to approximately 700 micrometers.

As shown in FIG. 2C, following the wafer grinding operation, an insulator layer 204 is deposited on the first semiconductor layer 102. A deposition tool may be used to deposit the insulator layer 204 using a PVD technique, an ALD technique, a CVD technique, an oxidation technique, and/or another suitable deposition technique. In some implementations, a planarization tool may be used to perform a planarization operation such as a CMP operation to planarize the insulator layer 204 after the insulator layer 204 is deposited. In some implementations, the insulator layer 204 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. In some implementations, a thickness of the insulator layer 204 may be included in a range of approximately 300 nanometers to approximately 2000 nanometers. However, other values for the range are within the scope of the present disclosure.

Following deposition of the insulator layer 204, a plurality of recesses 206 are formed. The interconnect structures including the barrier layers 128 and interconnect fill layers 130 may be formed in the recesses 206. In some implementations, an etch tool may be used to etch a dielectric masking layer based on a pattern corresponding to the locations of the recesses 206 in a photoresist layer, to transfer the pattern to the dielectric masking layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

Multiple etch operations may be performed to etch the insulator layer 204, the first semiconductor layer 102 down to the insulator layer 104, the insulator layer 104, and then the second semiconductor layer 106 down to the sacrificial insulator layer 202. In order to perform the multiple etch operations, the semiconductor device 100 may be transferred between different etch tools using a wafer/die transport tool to reduce the likelihood of cross-contamination between different etchants and etch tools. Alternatively, an etch tool that has multiple processing chambers (e.g., a cluster tool) may be used, and the semiconductor device 100 may be transferred between processing chambers of the etch tool for etching using different types of etchants. The multiple etch operations may include one or more dry etch operations (e.g., plasma-based etch operations, gas-based etch operations), one or more wet chemical etch operations, and/or other types of etch operations. For example, a gas-based etchant may include a fluorine-based gas etchant such as a carbon-fluoride-based (CFₓ) gas etchant such as a carbon tetrafluoride (CF₄) gas etchant. In some implementations, a width in the x-direction of the recesses 206 may be included in a range of approximately 1 micrometer to approximately 100 micrometers, and a depth in the z-direction of the recesses 206 may be included in a range of approximately 200 micrometers to approximately 700 micrometers. However, other values for the ranges are within the scope of the present disclosure. Following formation of the recesses 206, the liner insulator layer 126 is deposited on sidewalls and bottom surfaces of the recesses 206 using a conformal deposition technique, such as, for example, CVD or ALD.

As shown in FIG. 2D, the barrier layer 128 is deposited on the insulator layer 204 and on the liner insulator layer 126, and on the sidewalls and bottom surfaces of the recesses 206 using a conformal deposition technique, such as, for example, CVD or ALD. Then, a seed layer for the formation of the interconnect fill layer 130 is deposited on the barrier layer 128 using a conformal deposition technique, such as, for example, CVD or ALD. In some implementations, a combined thickness of the barrier layer 128 and the seed layer may be included in a range of approximately 300 angstroms to approximately 3000 angstroms. Following deposition of the barrier layer 128 and the seed layer, the interconnect fill layer 130 is deposited on the first side of the semiconductor layer 102 and in the recesses 206 to fill in remaining portions of the recesses 206. In some implementations, a deposition tool is used to deposit the interconnect fill layer 130 using a PVD technique, a CVD technique, an ALD technique, and/or another suitable deposition technique.

As shown in FIG. 2E, a planarization process (e.g., CMP) is performed to remove portions of the barrier layer 128, the seed layer, and the interconnect fill layer 130 from a top surface of the insulator layer 204. Following the planarization process, surfaces of the interconnect structures including the barrier layers 128 and interconnect fill layers 130a and 130b are exposed at the top of the recesses 206. As shown by the arrow R, the exposed surfaces of the interconnect structures may be recessed with respect to the top surface of the insulator layer 204.

As shown in FIG. 2F, the plurality of conductive adhesion layers 132 and the plurality of conductive routing layers 134a and 134b are formed on the exposed surfaces of the interconnect structures including the barrier layers 128 and interconnect fill layers 130a and 130b. A deposition tool may be used to deposit a blanket layer to form the plurality of conductive adhesion layers 132 using a PVD technique, an ALD technique, a CVD technique, and/or another suitable deposition technique. The blanket layer to form the plurality of conductive adhesion layers 132 is deposited on the top surface of the insulator layer 204, and on exposed surfaces of the interconnect structures. A deposition tool may be used to deposit a blanket layer to form the plurality of conductive routing layers 134a and 134b using a PVD technique, an ALD technique, a CVD technique, and/or another suitable deposition technique. The blanket layer to form the plurality of conductive routing layers 134a and 134b is deposited on the blanket layer to form the plurality of conductive adhesion layers 132. Following the deposition of the blanket layers, portions of the blanket layers are removed in one or more etching operations to result in the plurality of conductive adhesion layers 132, and the plurality of conductive routing layers 134a and 134b. In some implementations, a hard mask layer may be formed on portions of the conductive routing layer blanket layer corresponding to where the plurality of conductive adhesion layers 132 and the plurality of conductive routing layers 134a and 134b are to be formed. An etch tool may be used to etch exposed portions of the conductive routing layer blanket layer, and underlying portions of the conductive adhesion layer blanket layer based on the hard mask layer, to define the plurality of conductive adhesion layers 132, and the plurality of conductive routing layers 134a and 134b.

As shown in FIG. 2F, in some implementations, parts of respective ones of the plurality of conductive adhesion layers 132 are formed in a U-shape due to the exposed surfaces of the interconnect structures being recessed with respect to the top surface of the insulator layer 204. Similarly, in some implementations, bottom parts of respective ones of the plurality of conductive routing layers 134a and 134b have a smaller width in the x-direction than top parts of the respective ones of the plurality of conductive routing layers 134a and 134b due to the exposed surfaces of the interconnect structures being recessed with respect to the top surface of the insulator layer 204.

As shown in FIG. 2G, the bottom insulator layer 124 is deposited on and around the plurality of conductive routing layers 134a and 134b and the plurality of conductive adhesion layers 132 to embed the plurality of conductive routing layers 134a and 134b and the plurality of conductive adhesion layers 132 in the bottom insulator layer 124. A deposition tool may be used to deposit the bottom insulator layer 124 using a PVD technique, an ALD technique, a CVD technique, an oxidation technique, and/or another suitable deposition technique. In some implementations, a thickness of the bottom insulator layer 124 may be included in a range of approximately 300 nanometers to approximately 1000 nanometers. However, other values for the range are within the scope of the present disclosure. In some implementations, a planarization tool may be used to perform a planarization operation such as a CMP operation to planarize the bottom insulator layer 124 after the bottom insulator layer 124 is deposited.

Following the planarization operation, a deposition tool may be used to deposit the passivation layer 136 on the bottom insulator layer 124 using a PVD technique, an ALD technique, a CVD technique, an oxidation technique, and/or another suitable deposition technique. Then, a deposition tool may be used to deposit another sacrificial insulator layer 208 on the passivation layer 136 using a PVD technique, an ALD technique, a CVD technique, an oxidation technique, and/or another suitable deposition technique. In some implementations, the other sacrificial insulator layer 208 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. In some implementations, a thickness of the other sacrificial insulator layer 208 may be included in a range of approximately 1500 nanometers to approximately 3000 nanometers. However, other values for the range are within the scope of the present disclosure.

As shown in FIG. 2H, following deposition of the other sacrificial insulator layer 208, the resulting structure is flipped (e.g., rotated 180 degrees) using a wafer/die transport tool so that the sacrificial insulator layer 202 is at a top of the structure instead of a bottom of the structure in the z-direction, and the other sacrificial insulator layer 208 is at a bottom of the structure instead of a top of the structure in the z-direction. The semiconductor device 100 may be attached to a carrier wafer (not shown), which can be attached to the wafer/die transport tool to perform the rotation. The carrier wafer may be removed after performing the rotation.

As shown in FIG. 2I, following the flipping process, the sacrificial insulator layer 202 may be removed in an etching operation performed by an etch tool. The etch operation may include a dry etch operation (e.g., a plasma-based etch operation, a gas-based etch operation), a wet chemical etch operation, and/or another type of etch operation. For example, a gas-based etchant may include a fluorine-based gas etchant such as a carbon-fluoride-based (CFₓ) gas etchant such as a carbon tetrafluoride (CF₄) gas etchant. The removal of the sacrificial insulator layer 202 exposes a top surface of the second semiconductor layer 106, and surfaces of the interconnect structures including the barrier layers 128 and the interconnect fill layers 130a and 130b on the second side of the semiconductor device 100.

As shown in FIG. 2J, a deposition tool may be used to deposit the base insulator layer 108 on a top surface of the second semiconductor layer 106 using a PVD technique, an ALD technique, a CVD technique, an oxidation technique, and/or another suitable deposition technique. Then, a deposition tool may be used to deposit the insulator adhesion layer 110 on a top surface of the base insulator layer 108. Following the deposition of the base insulator layer 108 and of the insulator adhesion layer 110, portions of the base insulator layer 108 and of the insulator adhesion layer 110 are removed in one or more etching operations. In some implementations, a hard mask layer may be formed on portions of the insulator adhesion layer 110 leaving other portions of the insulator adhesion layer 110 exposed, corresponding to where the base portions of the first electrode 112 and of the second electrode 114 are to be formed on exposed surfaces of the interconnect structures. An etch tool may be used to etch exposed portions of the insulator adhesion layer 110, and underlying portions of the base insulator layer 108 based on the hard mask layer, to define a plurality of openings exposing surfaces of the interconnect structures including the barrier layers 128 and the interconnect fill layers 130a and 130b.

Then, using a PVD technique, an ALD technique, a CVD technique, and/or another suitable deposition technique, a deposition tool may be used to deposit a conductive layer 210 on the insulator adhesion layer 110, and in the plurality of openings where the surfaces of the interconnect structures are exposed. In some implementations, the conductive layer 210 includes chemically inert metals that can be used for the first electrode 112 and the second electrode 114, such as platinum (Pt), molybdenum (Mo), and/or iridium (Ir), among other examples, and/or chemically inert metal compounds that can be used for the first electrode 112 and the second electrode 114, such as lanthanum nickel oxide (LNO) (LaNiOₓ such as LaNiO₃) and/or ruthenium oxide (RuOₓ such as RuO₂). In some implementations, the thickness of the conductive layer 210 may be included in a range of approximately 300 nanometers to approximately 2000 nanometers. However, other values for the range are within the scope of the present disclosure.

As shown in FIG. 2K, a deposition tool may be used to deposit the piezoelectric layer 116 on a top surface of the conductive layer 210 using a PVD technique, an ALD technique, a CVD technique, an oxidation technique, and/or another suitable deposition technique. Then, as shown in FIG. 2L, parts of the piezoelectric layer 116, parts of the conductive layer 210, and parts of the insulator adhesion layer 110 are removed in one or more etching operations. In some implementations, a hard mask layer may be formed on portions of the piezoelectric layer 116 corresponding to where the piezoelectric layer 116, and underlying portions of the conductive layer 210 and the insulator adhesion layer 110 are to remain. Multiple etch operations may be performed to etch the parts of the piezoelectric layer 116, the parts of the conductive layer 210, and the parts of the insulator adhesion layer 110. In order to perform the multiple etch operations, the semiconductor device 100 may be transferred between different etch tools using a wafer/die transport tool to reduce the likelihood of cross-contamination between different etchants and etch tools. Alternatively, an etch tool that has multiple processing chambers (e.g., a cluster tool) may be used, and the semiconductor device 100 may be transferred between processing chambers of the etch tool for etching using different types of etchants. The multiple etch operations may include one or more dry etch operations (e.g., plasma-based etch operations, gas-based etch operations), one or more wet chemical etch operations, and/or other types of etch operations. For example, a gas-based etchant may include a fluorine-based gas etchant such as a carbon-fluoride-based (CFₓ) gas etchant such as a carbon tetrafluoride (CF₄) gas etchant. As shown in FIG. 2L, the base portions of the first electrodes 112 and of the second electrodes 114, and the piezoelectric layers 116 on top surfaces of parts of the first electrodes 112 remain after the one or more etch operations.

As shown in FIG. 2M, a deposition tool may be used to deposit the first adhesion layer 118 using a conformal deposition technique, such as an ALD technique, a CVD technique, and/or another suitable deposition technique. The first adhesion layer 118 may be deposited between, over, and/or on parts of the first electrode 112 and of the second electrode 114, and over and/or on the base insulator layer 108 and/or the insulator adhesion layer 110. The first adhesion layer 118 may also be deposited between a first portion of the piezoelectric layer 116 on a first one of the first electrodes 112 and a second portion of the piezoelectric layer 116 on a second one of the first electrodes 112.

As shown in FIG. 2N, a portion of the first adhesion layer 118 is etched to create an opening 212 between the first portion of the piezoelectric layer 116 on the first one of the first electrodes 112 and the second portion of the piezoelectric layer 116 on the second one of the first electrodes 112. The portion of the first adhesion layer 118 may be removed in an etching operation performed by an etch tool. The etch operation may include a dry etch operation (e.g., a plasma-based etch operation, a gas-based etch operation), a wet chemical etch operation, and/or another type of etch operation. The etching removes the portion of the first adhesion layer 118 to expose a surface of the base insulator layer 108.

As shown in FIG. 2O, a deposition tool may be used to deposit the passivation layer 120 and the second adhesion layer 122 using a conformal deposition technique, such as an ALD technique, a CVD technique, and/or another suitable deposition technique. The passivation layer 120 may be deposited on the first adhesion layer 118, and fills in areas between parts of the first electrode 112 and of the second electrode 114. The passivation layer 120 further fills in the at least part of the opening 212 between the first portion of the piezoelectric layer 116 on the first one of the first electrodes 112 and the second portion of the piezoelectric layer 116 on the second one of the first electrodes 112. The second adhesion layer 122 may be deposited on the passivation layer 120, and fills in at least part of the opening 212 between the first portion of the piezoelectric layer 116 on the first one of the first electrodes 112 and the second portion of the piezoelectric layer 116 on the second one of the first electrodes 112.

As shown in FIG. 2P, a portion of the second adhesion layer 122 is etched to create an opening 214 at a central portion of the stack comprising the first adhesion layer 118, the passivation layer 120, and the second adhesion layer 122. The portion of the second adhesion layer 122 may be removed in an etching operation performed by an etch tool. The etch operation may include a dry etch operation (e.g., a plasma-based etch operation, a gas-based etch operation), a wet chemical etch operation, and/or another type of etch operation.

As shown in FIG. 2Q, portions of the second adhesion layer 122, of the passivation layer 120, and of the first adhesion layer 118 are etched to create openings 216 exposing surfaces of the base portions of the second electrodes 114, and openings 218 exposing surfaces of the piezoelectric layers 116. Remaining portions of the second electrodes 114 may be formed in the openings 216 and 218 on the exposed surfaces of the base portions of the second electrodes 114, and on the exposed surfaces of the piezoelectric layers 116. The portions of the second adhesion layer 122, of the passivation layer 120, and of the first adhesion layer 118 may be removed in one or more etching operations performed by an etch tool. The one or more etching operations may include one or more dry etch operations (e.g., plasma-based etch operations, gas-based etch operations), one or more wet chemical etch operations, and/or other types of etch operations.

As shown in FIG. 2R, a deposition tool is used to deposit remaining portions of the second electrodes 114 using a PVD technique, an ALD technique, a CVD technique, and/or another suitable deposition technique. The remaining portions of the second electrodes 114 are deposited in the openings 216 and 218 on the exposed surfaces of the base portions of the second electrodes 114, and on the exposed surfaces of the piezoelectric layers 116. In addition, the remaining portions of the second electrodes 114 are deposited on exposed surfaces of the first adhesion layer 118, of the passivation layer 120, and of the second adhesion layer 122. The remaining portions of respective second electrodes 114 physically contact and extend from respective base portions of the second electrodes 114.

As shown in FIG. 2S, multiple etch operations may be performed to etch the passivation layer 120, the base insulator layer 108, and the second semiconductor layer 106 down to the insulator layer 104 to form the second cavity 142. In order to perform the multiple etch operations, the semiconductor device 100 may be transferred between different etch tools using a wafer/die transport tool to reduce the likelihood of cross-contamination between different etchants and etch tools. Alternatively, an etch tool that has multiple processing chambers (e.g., a cluster tool) may be used, and the semiconductor device 100 may be transferred between processing chambers of the etch tool for etching using different types of etchants. The multiple etch operations may include one or more dry etch operations (e.g., plasma-based etch operations, gas-based etch operations), one or more wet chemical etch operations, and/or other types of etch operations. For example, a gas-based etchant may include a fluorine-based gas etchant such as a carbon-fluoride-based (CFₓ) gas etchant such as a carbon tetrafluoride (CF₄) gas etchant. The second cavity 142 separates the left section A from the right section B. The left section A includes the first piezoelectric structure including a first electrode 112, a second electrode 114, and a piezoelectric layer 116 to the left of the second cavity 142 (e.g., in the x-direction). The right section B includes the second piezoelectric structure including a first electrode 112, a second electrode 114, and a piezoelectric layer 116 to the right of the second cavity 142 (e.g., in the x-direction).

As shown in FIG. 2T, an adhesive 220 is deposited on exposed surfaces of the passivation layer 120, on exposed surfaces of the second electrode 114, and in the second cavity 142 to attach a carrier wafer 222 to the semiconductor device 100. The adhesive may be, for example, a polymeric material, such as a polyimide-based material, and/or a thermoplastic polymer. The carrier wafer 222 may be, for example, a glass carrier wafer. The resulting structure is flipped (e.g., rotated 180 degrees) using a wafer/die transport tool so that the other sacrificial insulator layer 208 is at a top of the structure instead of a bottom of the structure in the z-direction, and the second electrode 114 is at a bottom of the structure instead of a top of the structure in the z-direction. The carrier wafer 222 can be attached to the wafer/die transport tool to perform the rotation.

Following the flipping process, the other sacrificial insulator layer 208 may be removed in an etching operation performed by an etch tool. The etch operation may include a dry etch operation (e.g., a plasma-based etch operation, a gas-based etch operation), a wet chemical etch operation, and/or another type of etch operation. For example, a gas-based etchant may include a fluorine-based gas etchant such as a carbon-fluoride-based (CFₓ) gas etchant such as a carbon tetrafluoride (CF₄) gas etchant. The removal of the other sacrificial insulator layer 208 exposes a surface of the passivation layer 136.

Then, portions of the passivation layer 136 and of the bottom insulator layer 124 are removed in one or more etching operations. In some implementations, a hard mask layer may be formed on portions of the passivation layer 136, leaving other portions of the passivation layer 136 exposed, corresponding to where the cavity 140 is to be formed. An etch tool may be used to etch exposed portions of the passivation layer 136, and underlying portions of the bottom insulator layer 124 based on the hard mask layer to expose a portion of the first semiconductor layer 102.

As shown in FIG. 2U, using a PVD technique, an ALD technique, a CVD technique, an oxidation technique, and/or another suitable deposition technique, a deposition tool is used to deposit additional portions of the passivation layer 136 on exposed side surfaces of the bottom insulator layer 124, and on surfaces of the first semiconductor layer 102 adjacent to the exposed side surfaces of the bottom insulator layer 124. In some implementations, a thickness of the additional portions of the passivation layer 136 may be included in a range of approximately 300 nanometers to approximately 1500 nanometers. However, other values and ranges are within the scope of the present disclosure.

As shown in FIG. 2V, portions of the passivation layer 136 and of the bottom insulator layer 124 over the conductive routing layers 134a and 134b are removed in one or more etching operations to create the openings 138 exposing portions of respective ones of the conductive routing layers 134a and 134b. In some implementations, a hard mask layer may be formed on portions of the passivation layer 136 that are to remain after the etching. An etch tool may be used to etch exposed portions of the passivation layer 136 and underlying portions of the bottom insulator layer 124 based on the hard mask layer to define the openings 138 exposing portions of respective ones of the conductive routing layers 134a and 134b.

As shown in FIG. 2W, multiple etch operations may be performed to etch exposed portions of the first semiconductor layer 102 down to the insulator layer 104, and the underlying portion of the insulator layer 104, to form the first cavity 140. In order to perform the multiple etch operations, the semiconductor device 100 may be transferred between different etch tools using a wafer/die transport tool to reduce the likelihood of cross-contamination between different etchants and etch tools. Alternatively, an etch tool that has multiple processing chambers (e.g., a cluster tool) may be used, and the semiconductor device 100 may be transferred between processing chambers of the etch tool for etching using different types of etchants. The multiple etch operations may include one or more dry etch operations (e.g., plasma-based etch operations, gas-based etch operations), one or more wet chemical etch operations, and/or other types of etch operations. For example, a gas-based etchant may include a fluorine-based gas etchant such as a carbon-fluoride-based (CFₓ) gas etchant such as a carbon tetrafluoride (CF₄) gas etchant.

As shown in FIG. 2X, following formation of the cavity 140, the resulting structure is flipped (e.g., rotated 180 degrees using a wafer/die transport tool) so that the second electrodes 114 are at a top of the structure instead of a bottom of the structure in the z-direction, and the passivation layer 136 and conductive routing layers 134a and 134b are at a bottom of the structure instead of a top of the structure in the z-direction. The carrier wafer 222 may be removed after performing the rotation. A laser glass carrier de-bonding operation may be performed to remove the carrier wafer 222. Following the de-bonding operation, residues from the adhesive 220 and/or the carrier wafer 222 may be removed in a cleaning operation. The cleaning operation may include immersing de-bonded areas in a cleaning solution for a pre-determined time period and/or performing an ashing operation to remove the residues.

As indicated above, FIGS. 2A-2X are provided as an example. Other examples may differ from what is described with regard to FIGS. 2A-2X.

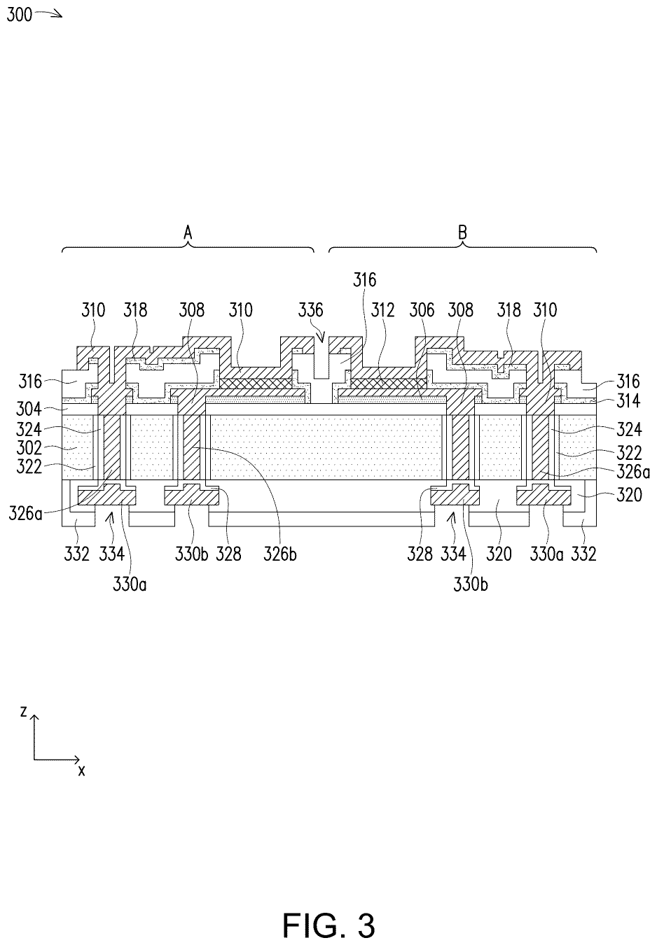

FIG. 3 is a diagram of an example semiconductor device 300 described herein. The semiconductor device 300 may include a memory structure, such as a ferroelectric random-access memory (FRAM) memory structure, among other examples. In the memory structure, a piezoelectric layer functions as a switching layer. As shown in FIG. 3, the semiconductor device 300 may include a substrate 302 having one or more semiconductor layers. The substrate 302 may include a silicon (Si) substrate, a substrate formed of a material including silicon, a III-V compound semiconductor material substrate such as gallium arsenide (GaAs), an SOI substrate, a germanium (Ge) substrate, a silicon germanium (SiGe) substrate, or another type of semiconductor substrate. The semiconductor device 300 may be cut or diced from a semiconductor wafer after or as a part of manufacturing of the semiconductor device 300. The semiconductor wafer may be a round/circular wafer. The substrate 302 may be any square, rectangular, curved, or otherwise non-circular workpiece, such as a polygonal substrate.

The semiconductor device 300 includes a similar combination of structures and/or layers as the semiconductor device 100. For example, the semiconductor device 300 may include elements 304-332, which are similar to the elements 108-136 of the semiconductor device 100.

However, the semiconductor device 300 includes the substrate 302, which is a bulk substrate comprising a single semiconductor layer, while the semiconductor device 100 includes the SOI substrate including the first semiconductor layer 102, the insulator layer 104, and the second semiconductor layer 106. In addition, the first cavity 140 is omitted from (and not formed in) the semiconductor device 300 because of the semiconductor device 300 including a memory structure (e.g., an FRAM structure) as opposed to a MEMS device. Moreover, piezoelectric layers 312 are included in the semiconductor device 300 instead of the piezoelectric layers 116 as in the semiconductor device 100. The piezoelectric layers 312 are similar to the piezoelectric layers 116 and include similar piezoelectric material(s). However, the piezoelectric layers 312 in the semiconductor device 300 are implemented as ferroelectric layers (e.g., switching layers) for a memory device (e.g., an FRAM structure). The piezoelectric materials used for the piezoelectric layers 116 and 312 also exhibit ferroelectric properties and pyroelectric properties. Therefore, the polarity of atoms in the piezoelectric layer 312 between a first electrode 308 and a second electrode 310 in the semiconductor device 300 can be switched or modified based on the polarity in an electric field applied across the piezoelectric layer 312.

When a voltage is applied to a first electrode 308 and a second electrode 310 through conductive routing layers 330, and interconnect structures including barrier layers 324 and interconnect fill layers 326, an electric field is generated across a piezoelectric layer 312 disposed between the first electrode 308 and the second electrode 310. Dipoles in the piezoelectric layer 312 align with the electric field in a designated polarity state, which may correspond to a “0” state and “1” state. After the electric field is removed, the dipoles maintain the polarity state, with 0 corresponding to a negative voltage, and 1 corresponding to a positive voltage. Writing to an FRAM structure may occur by applying a voltage to the first electrode 308 and the second electrode 310 on either side of the piezoelectric layer 312, which causes the atoms in the piezoelectric layer 312 to be in a first orientation (e.g., “up”) or a second orientation opposite to the first orientation (e.g., “down”). The orientation depends on the polarity of the charge, and determines whether a 0 or 1 is stored. When reading from an FRAM structure is performed, a piezoelectric layer 312 may be forced into a particular state (e.g., 0 or 1) by the application of voltage to the first electrode 308 and the second electrode 310. If the piezoelectric layer 312 was already in that state, minimal current will flow. However, if the piezoelectric layer 312 was in a different state, more current flows to change the state. The difference in current allows for a determination of which state the piezoelectric layer 312 was in prior to the read operation.

Since the operation of the semiconductor device 300 is not based on mechanical actuation such as vibration of piezoelectric layer 312, the first cavity 140 may be omitted from the semiconductor device 300. In the semiconductor device 300, first and second piezoelectric structures in a left section A and a right section B of the semiconductor device 300 are separated from each other by a cavity 336 (e.g., an air gap), and a passivation layer 316 under the cavity 336. The first and second piezoelectric structures each include a first electrode 308, a second electrode 310, and a piezoelectric layer 312 between the first electrode 308 and the second electrode 310. The cavity 336 of the semiconductor device 300 is similar to the second cavity 142 of the semiconductor device 100. However, unlike the second cavity 142, which is open at top and bottom ends, the cavity 336 is open at a top end, but closed at a bottom end due to the presence of the passivation layer 316.

As referred to herein, the bottom insulator layer 320 and components in and/or under the bottom insulator layer 320 are on a first side (e.g., a bottom side) of the semiconductor device 300 or of the substrate 302. As referred to herein, the base insulator layer 304 and components in and/or over the base insulator layer 304 are on a second side (e.g., a top side) of the semiconductor device 300 or of the substrate 302. The second side (e.g., top side) is opposite the first side (e.g., bottom side) in the z-direction.

As indicated above, FIG. 3 is provided as an example. Other examples may differ from what is described with regard to FIG. 3.

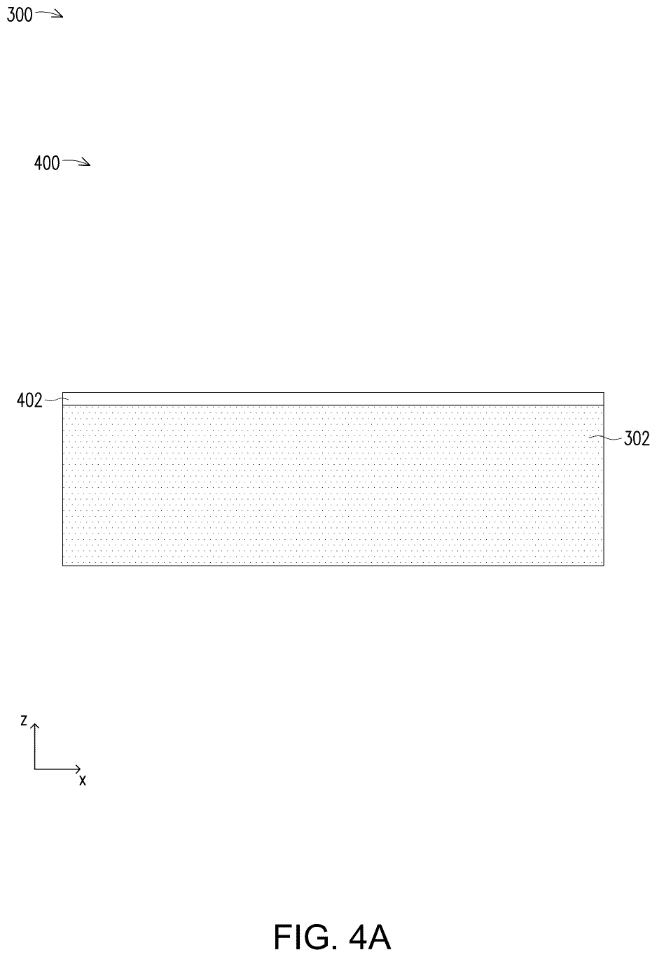

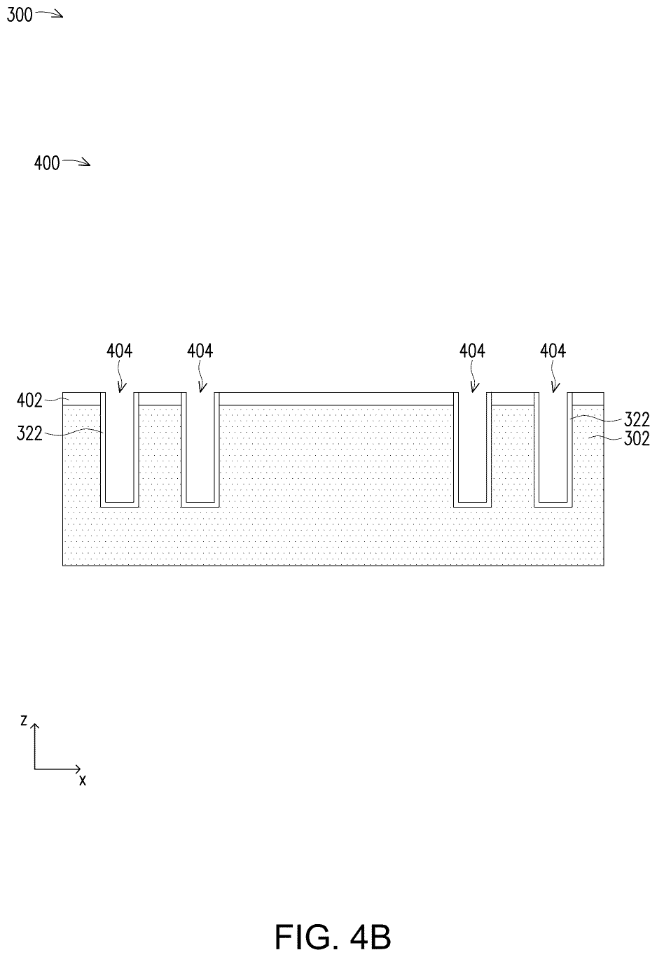

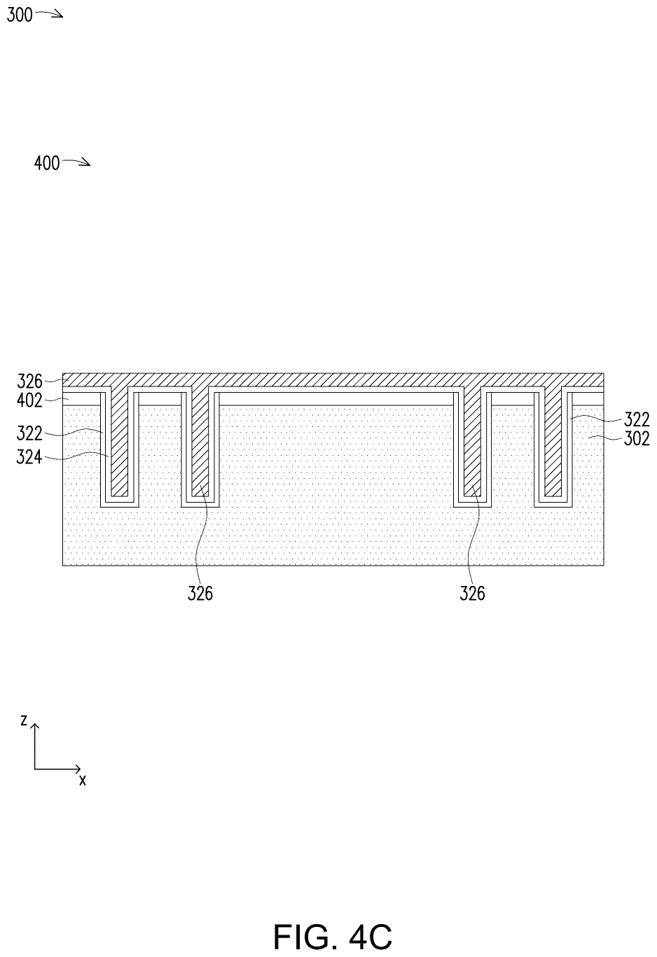

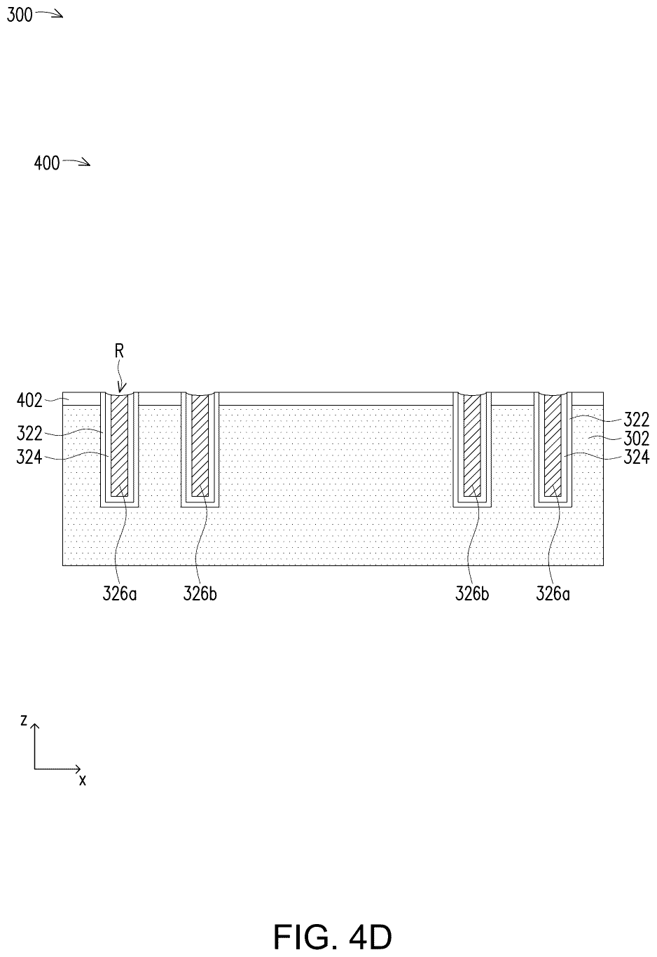

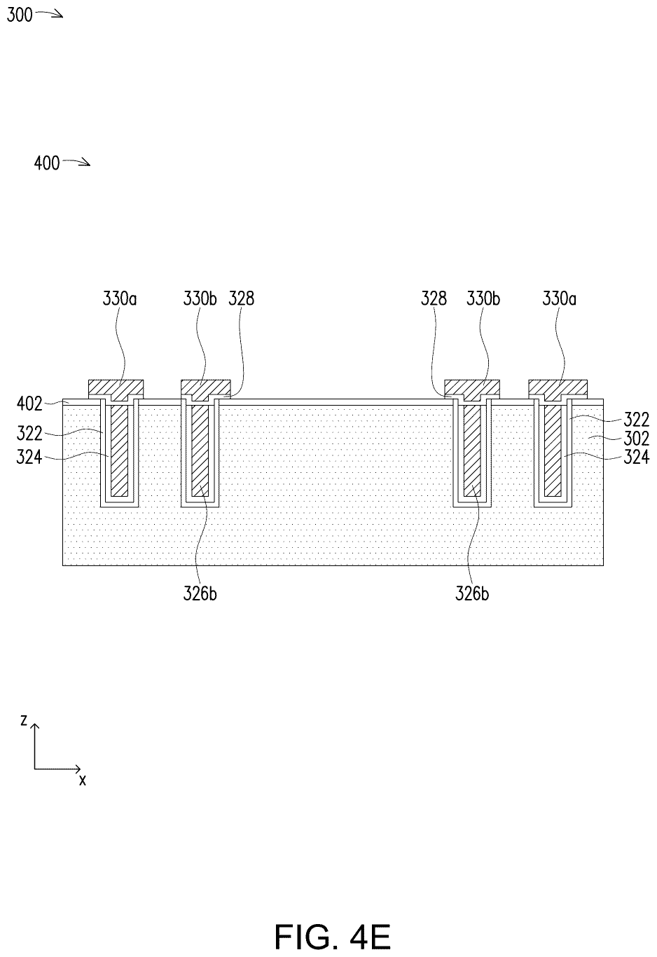

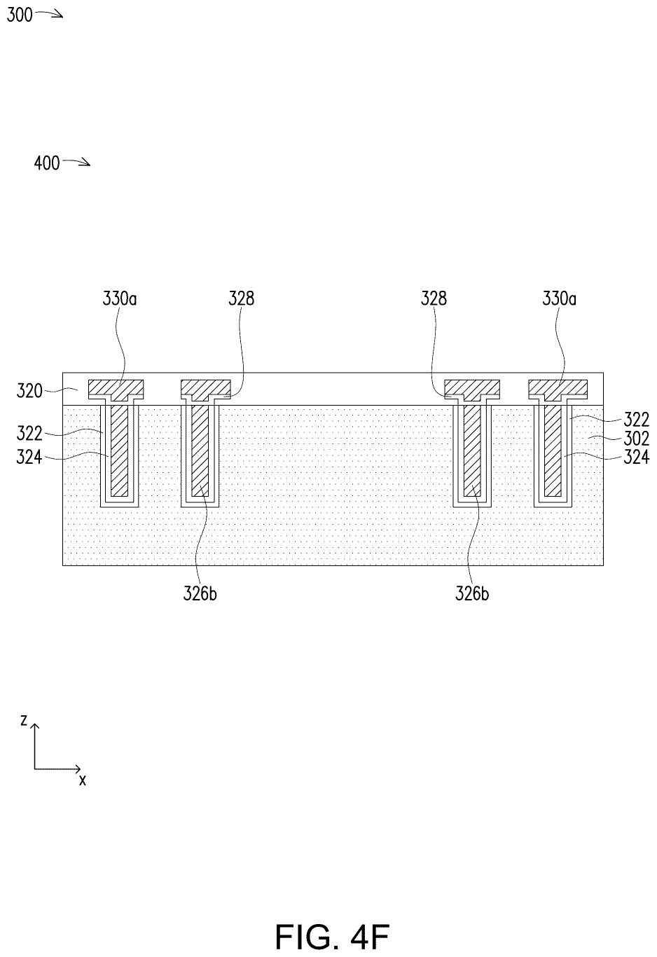

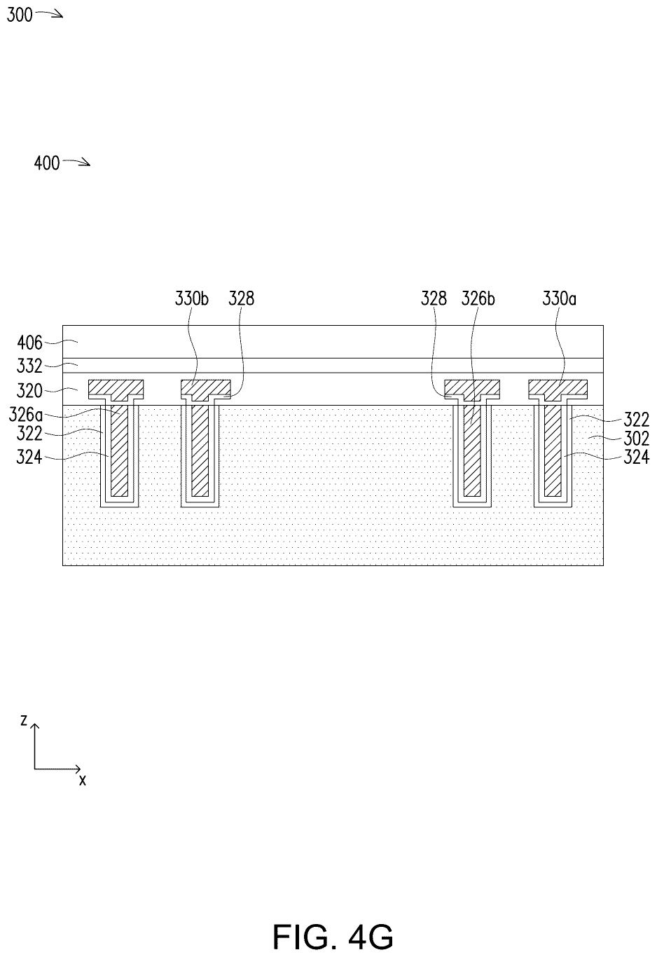

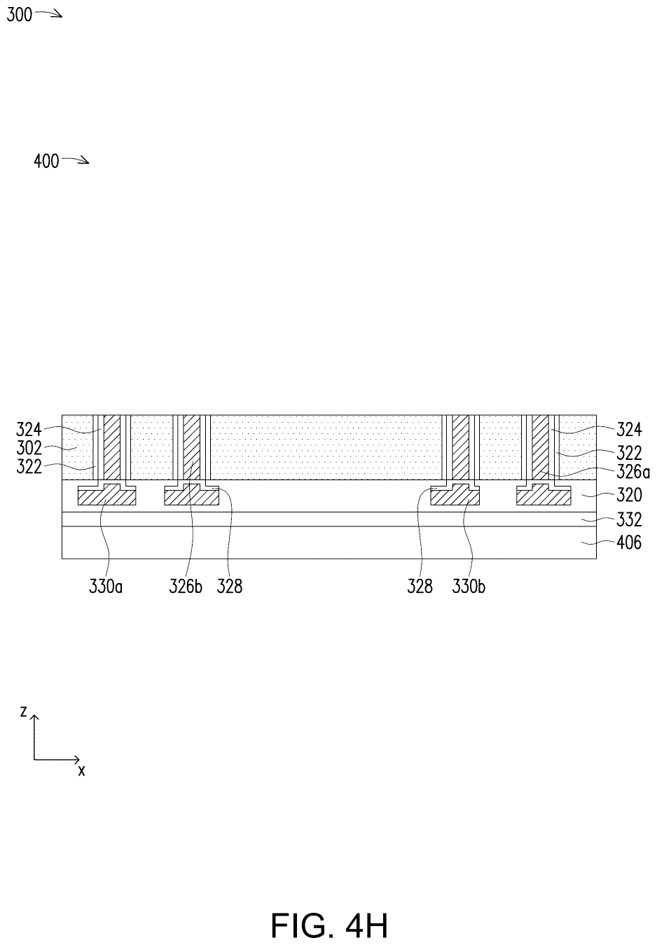

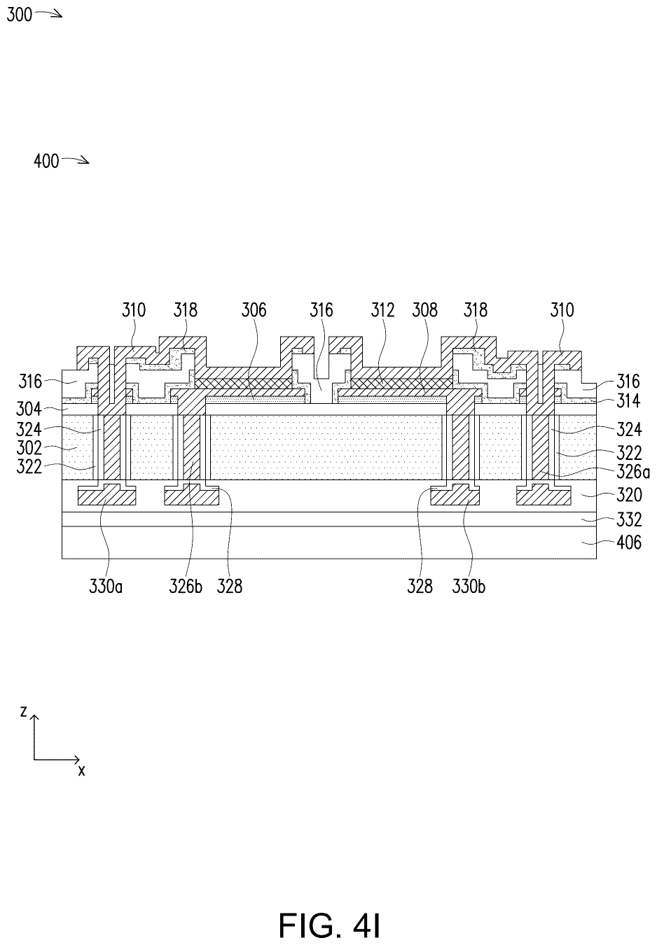

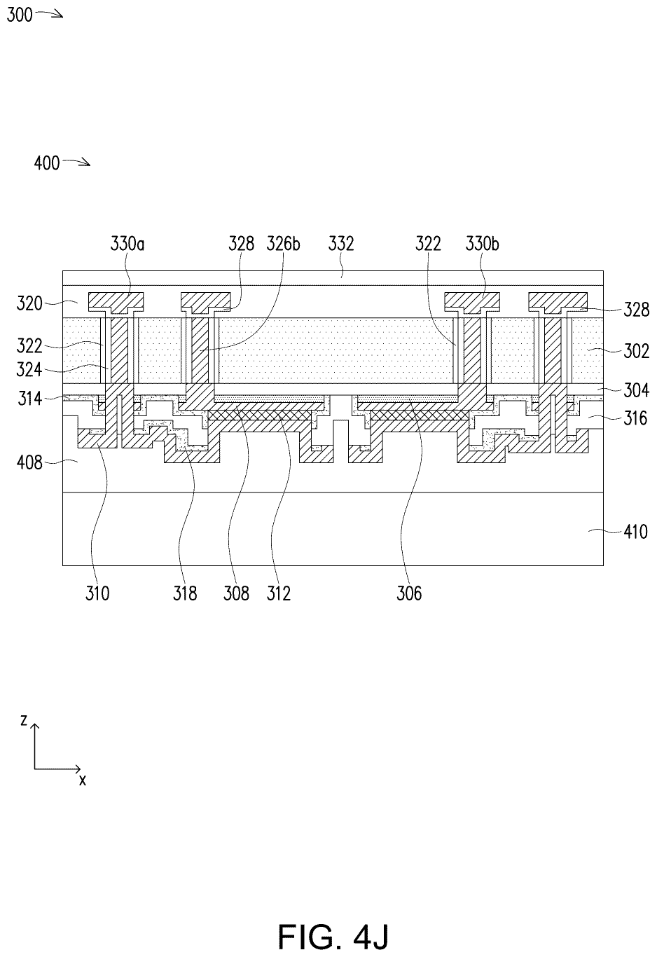

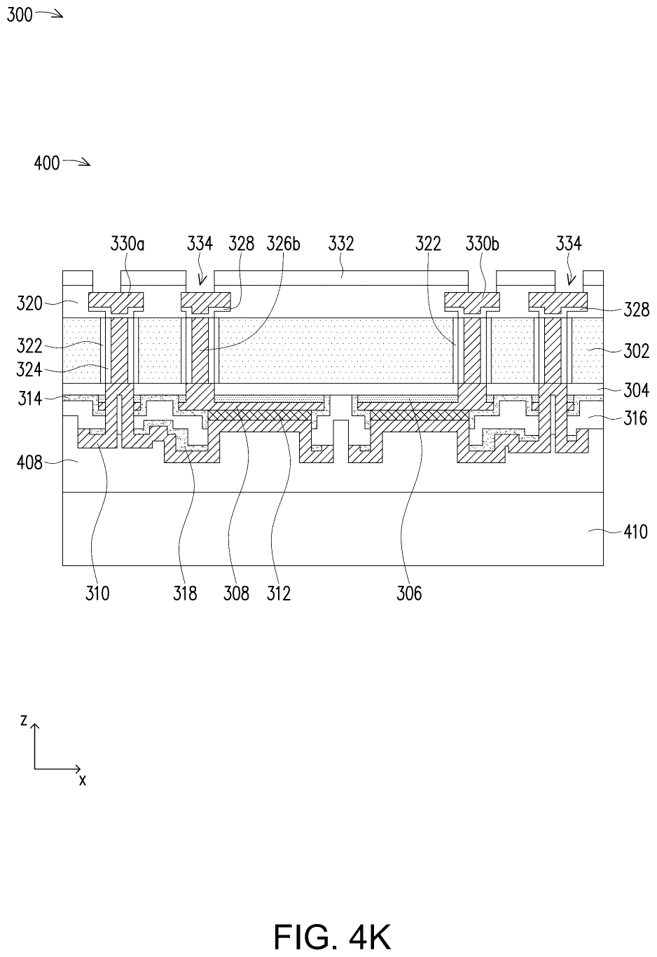

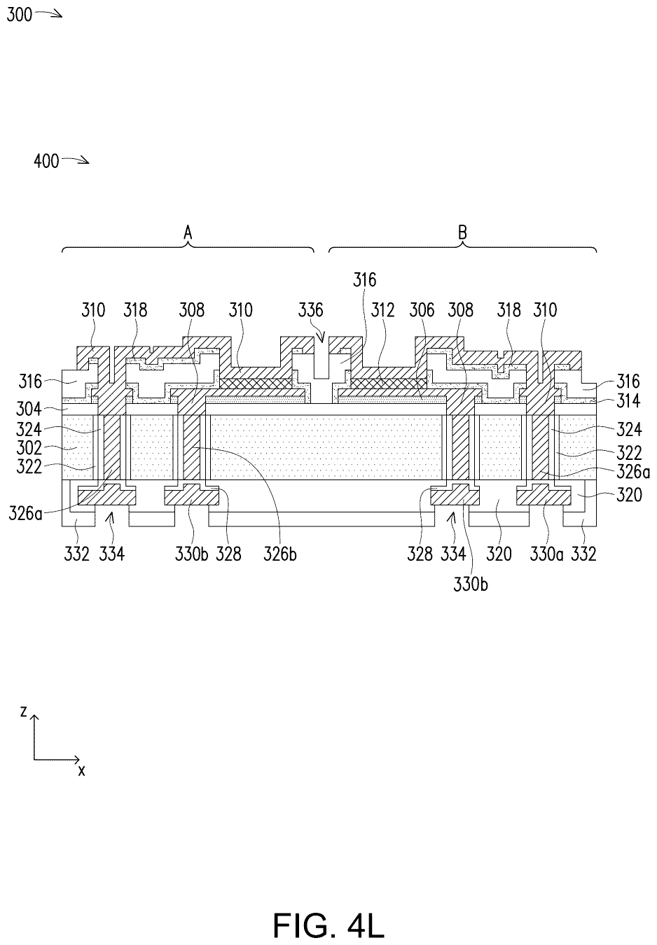

FIGS. 4A-4L are diagrams of an example implementation 400 of forming a semiconductor device 300 described herein. In some implementations, one or more of the semiconductor processing operations described in connection with FIGS. 4A-4L may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 4A, the substrate 302 is provided. The substrate 302 may be provided in the form of a semiconductor wafer such as a silicon wafer, and/or another type of semiconductor work piece. The semiconductor device 300 may be formed on the semiconductor wafer with other semiconductor devices. A deposition tool may be used to deposit an insulator layer 402 on a top surface of the substrate 302 using a PVD technique, an ALD technique, a CVD technique, an oxidation technique, and/or another suitable deposition technique. In some implementations, a planarization tool may be used to perform a planarization operation such as a CMP operation to planarize the insulator layer 402 after the insulator layer 402 is deposited. In some implementations, the insulator layer 402 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. In some implementations, a thickness of the insulator layer 402 may be included in a range of approximately 300 nanometers to approximately 2000 nanometers. However, other values for the range are within the scope of the present disclosure.

As shown in FIG. 4B, following deposition of the insulator layer 402, a plurality of recesses 404 are formed. The interconnect structures including the barrier layers 324 and interconnect fill layers 326 (e.g., 326a and 326b) may be formed in the recesses 206. In some implementations, an etch tool may be used to etch a dielectric masking layer based on a pattern corresponding to the locations of the recesses 404 in a photoresist layer, to transfer the pattern to the dielectric masking layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

Multiple etch operations may be performed to etch the insulator layer 402 and a portion of the substrate 302. In order to perform the multiple etch operations, the semiconductor device 300 may be transferred between different etch tools using a wafer/die transport tool to reduce the likelihood of cross-contamination between different etchants and etch tools. Alternatively, an etch tool that has multiple processing chambers (e.g., a cluster tool) may be used, and the semiconductor device 300 may be transferred between processing chambers of the etch tool for etching using different types of etchants. The multiple etch operations may include one or more dry etch operations (e.g., plasma-based etch operations, gas-based etch operations), one or more wet chemical etch operations, and/or other types of etch operations. For example, a gas-based etchant may include a fluorine-based gas etchant such as a carbon-fluoride-based (CFₓ) gas etchant such as a carbon tetrafluoride (CF₄) gas etchant. In some implementations, a width in the x-direction of the recesses 404 may be included in a range of approximately 1 micrometer to approximately 100 micrometers, and a depth in the z-direction of the recesses 404 may be included in a range of approximately 200 micrometers to approximately 700 micrometers. However, other values for the ranges are within the scope of the present disclosure. Following formation of the recesses 404, the liner insulator layer 322 is deposited on sidewalls and bottom surfaces of the recesses 404 using a conformal deposition technique, such as, for example, CVD or ALD.

As shown in FIG. 4C, the barrier layer 324 is deposited on the insulator layer 402 and on the liner insulator layer 322, and on the sidewalls and bottom surfaces of the recesses 404 using a conformal deposition technique, such as, for example, CVD or ALD. Then, a seed layer for the formation of the interconnect fill layer 326 is deposited on the barrier layer 324 using a conformal deposition technique, such as, for example, CVD or ALD. In some implementations, a combined thickness of the barrier layer 324 and the seed layer may be included in a range of approximately 300 angstroms to approximately 3000 angstroms. Following deposition of the barrier layer 324 and the seed layer, the interconnect fill layer 326 is deposited on the first side of the substrate 302 and in the recesses 404 to fill in remaining portions of the recesses 404. In some implementations, a deposition tool is used to deposit the interconnect fill layer 326 using a PVD technique, a CVD technique, an ALD technique, and/or another suitable deposition technique.

As shown in FIG. 4D, a planarization process (e.g., CMP) is performed to remove portions of the barrier layer 324, the seed layer, and the interconnect fill layer 326 from a top surface of the insulator layer 402. Following the planarization process, surfaces of the interconnect structures including the barrier layers 324 and interconnect fill layers 326a and 326b are exposed at the top of the recesses 404. As shown by the arrow R, the exposed surfaces of the interconnect structures may be recessed with respect to the top surface of the insulator layer 402.

As shown in FIG. 4E, the plurality of conductive adhesion layers 328 and the plurality of conductive routing layers 330a and 330b are formed on the exposed surfaces of the interconnect structures including the barrier layers 324 and interconnect fill layers 326a and 326b. A deposition tool may be used to deposit a blanket layer to form the plurality of conductive adhesion layers 328 using a PVD technique, an ALD technique, a CVD technique, and/or another suitable deposition technique. The blanket layer to form the plurality of conductive adhesion layers 328 is deposited on the top surface of the insulator layer 402, and on exposed surfaces of the interconnect structures. A deposition tool may be used to deposit a blanket layer to form the plurality of conductive routing layers 330a and 330b using a PVD technique, an ALD technique, a CVD technique, and/or another suitable deposition technique. The blanket layer to form the plurality of conductive routing layers 330a and 330b is deposited on the blanket layer to form the plurality of conductive adhesion layers 328. Following the deposition of the blanket layers, portions of the blanket layers are removed in one or more etching operations to result in the plurality of conductive adhesion layers 328, and the plurality of conductive routing layers 330a and 330b. In some implementations, a hard mask layer may be formed on portions of the conductive routing layer blanket layer corresponding to where the plurality of conductive adhesion layers 328 and the plurality of conductive routing layers 330a and 330b are to be formed. An etch tool may be used to etch exposed portions of the conductive routing layer blanket layer, and underlying portions of the conductive adhesion layer blanket layer based on the hard mask layer, to define the plurality of conductive adhesion layers 132 and the plurality of conductive routing layers 330a and 330b.

As shown in FIG. 4E, in some implementations, parts of respective ones of the plurality of conductive adhesion layers 328 are formed in a U-shape due to the exposed surfaces of the interconnect structures being recessed with respect to the top surface of the insulator layer 402. Similarly, in some implementations, bottom parts of respective ones of the plurality of conductive routing layers 330a and 330b have a smaller width in the x-direction than top parts of the respective ones of the plurality of conductive routing layers 330a and 330b, due to the exposed surfaces of the interconnect structures being recessed with respect to the top surface of the insulator layer 402.

As shown in FIG. 4F, the bottom insulator layer 320 is deposited on and around the plurality of conductive routing layers 330a and 330b and the plurality of conductive adhesion layers 328 to embed the plurality of conductive routing layers 330a and 330b and the plurality of conductive adhesion layers 328 in the bottom insulator layer 320. A deposition tool may be used to deposit the bottom insulator layer 320 using a PVD technique, an ALD technique, a CVD technique, an oxidation technique, and/or another suitable deposition technique. In some implementations, a thickness of the bottom insulator layer 320 may be included in a range of approximately 300 nanometers to approximately 1000 nanometers. However, other values for the range are within the scope of the present disclosure. In some implementations, a planarization tool may be used to perform a planarization operation such as a CMP operation to planarize the bottom insulator layer 320 after the bottom insulator layer 320 is deposited.

As shown in FIG. 4G, following the planarization operation, a deposition tool may be used to deposit the passivation layer 332 on the bottom insulator layer 320 using a PVD technique, an ALD technique, a CVD technique, an oxidation technique, and/or another suitable deposition technique. Then, a deposition tool may be used to deposit a sacrificial insulator layer 406 on the passivation layer 332 using a PVD technique, an ALD technique, a CVD technique, an oxidation technique, and/or another suitable deposition technique. In some implementations, the sacrificial insulator layer 406 may include an oxide-containing material, a nitride-containing material, a silicon oxide (SiOₓ such as SiO₂), a silicon nitride (SiₓN_{y}), aluminum oxide (AlₓO_{y} such as Al₂O₃), boron nitride (BN), and/or another dielectric material, among other examples. In some implementations, a thickness of the sacrificial insulator layer 406 may be included in a range of approximately 1500 nanometers to approximately 3000 nanometers. However, other values for the range are within the scope of the present disclosure.

As shown in FIG. 4H, following deposition of the sacrificial insulator layer 406, the resulting structure is flipped (e.g., rotated 180 degrees) using a wafer/die transport tool so that the sacrificial insulator layer 406 is at a bottom of the structure instead of a top of the structure in the z-direction. The semiconductor device 300 may be attached to a carrier wafer (not shown), which can be attached to the wafer/die transport tool to perform the rotation. The carrier wafer may be removed after performing the rotation.

Following the flipping process, a portion of the substrate 302 is removed in a grinding process to thin the substrate 302 (e.g., to reduce the thickness of the substrate 302). A planarization tool (e.g., a grinding tool) may perform a wafer grinding operation to mechanically grind silicon material away from the substrate 302. As a result of the wafer grinding operation, surfaces of the interconnect structures including the barrier layers 324 and the interconnect fill layers 326a and 326b on the second side of the semiconductor device 100 or substrate 302 are exposed.

Then, processing similar that described in connection with FIGS. 2I-2R is performed to result in the structure of FIG. 4I, where the formation and arrangement of elements 304-318 in the semiconductor device 300 is similar to the formation and arrangement of elements 108-122 in the semiconductor device 100.

As shown in FIG. 4J, an adhesive 408 is deposited on exposed surfaces of the passivation layer 316, on exposed surfaces of the second electrode 310, and in the cavity 336 to attach a carrier wafer 410 to the semiconductor device 300. The adhesive may be, for example, a polymeric material, such as a polyimide-based material, and/or a thermoplastic polymer. The carrier wafer 410 may be, for example, a glass carrier wafer. The resulting structure is flipped (e.g., rotated 180 degrees) using a wafer/die transport tool so that the sacrificial insulator layer 406 is at a top of the structure instead of a bottom of the structure in the z-direction, and the second electrode 310 is at a bottom of the structure instead of a top of the structure in the z-direction. The carrier wafer 410 can be attached to the wafer/die transport tool to perform the rotation.

Following the flipping process, the sacrificial insulator layer 406 may be removed in an etching operation performed by an etch tool. The etch operation may include a dry etch operation (e.g., a plasma-based etch operation, a gas-based etch operation), a wet chemical etch operation, and/or another type of etch operation. For example, a gas-based etchant may include a fluorine-based gas etchant such as a carbon-fluoride-based (CFₓ) gas etchant such as a carbon tetrafluoride (CF₄) gas etchant. The removal of the sacrificial insulator layer 406 exposes a surface of the passivation layer 332.

Then, as shown in FIG. 4K, portions of the passivation layer 332 and of the bottom insulator layer 320 over the conductive routing layers 330a and 330b are removed in an etching operation to create the openings 334, exposing portions of respective ones of the conductive routing layers 330a and 330b. In some implementations, a hard mask layer may be formed on portions of the passivation layer 332 that are to remain after the etching. An etch tool may be used to etch exposed portions of the passivation layer 332 and underlying portions of the bottom insulator layer 320 based on the hard mask layer to define the openings 334 exposing portions of respective ones of the conductive routing layers 330a and 330b.

As shown in FIG. 4L, following formation of the openings 334, the resulting structure is flipped (e.g., rotated 180 degrees) using a wafer/die transport tool so that the second electrodes 310 are at a top of the structure instead of a bottom of the structure in the z-direction, and the passivation layer 332 and conductive routing layers 330a and 330b are at a bottom of the structure instead of a top of the structure in the z-direction. The carrier wafer 410 may be removed after performing the rotation. A laser glass carrier de-bonding operation may be performed to remove the carrier wafer 410. Following the de-bonding operation, residues from the adhesive 408 and/or the carrier wafer 410 may be removed in a cleaning operation. The cleaning operation may include immersing de-bonded areas in a cleaning solution for a pre-determined time period and/or performing an ashing operation to remove the residues.

As indicated above, FIGS. 4A-4L are provided as an example. Other examples may differ from what is described with regard to FIGS. 4A-4L.

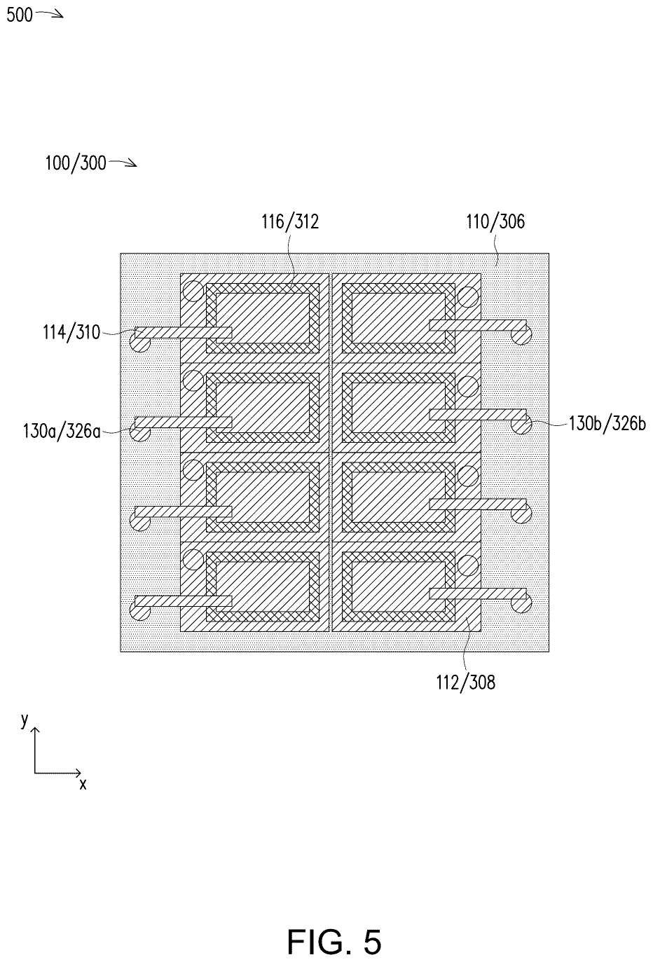

FIG. 5 is a diagram of an example implementation 500 of a semiconductor device 100 or 300 described herein. The example implementation 500 depicts a view from a second side (e.g., top side) of the semiconductor device 100 or 300 along the x-direction and the y-direction. An array of interconnect fill layers 130a/326a may be disposed under an insulator adhesion layer 110/306 and around a periphery of the semiconductor devices 100/300. An array of second electrodes 114/310 (e.g., top electrodes) land on and are physically in contact with the interconnect fill layers 130a/326a. Respective second electrodes 114/310 of the array of second electrodes 114/310 extend over and are in physical contact with respective piezoelectric layers 116/312 of an array of piezoelectric layers 116/312. Respective piezoelectric layers 116/312 are disposed on and in contact with respective first electrodes 112/306 (e.g., bottom electrodes) of an array of first electrodes 112/306. A portion of each of the first electrodes 112/306 is disposed on and is in physical contact with respective interconnect fill layers 130b/326b of an array of interconnect fill layers 130b/326b. The interconnect fill layers 130b/326b are positioned inward of the interconnect fill layers 130a/326a in the x-direction.

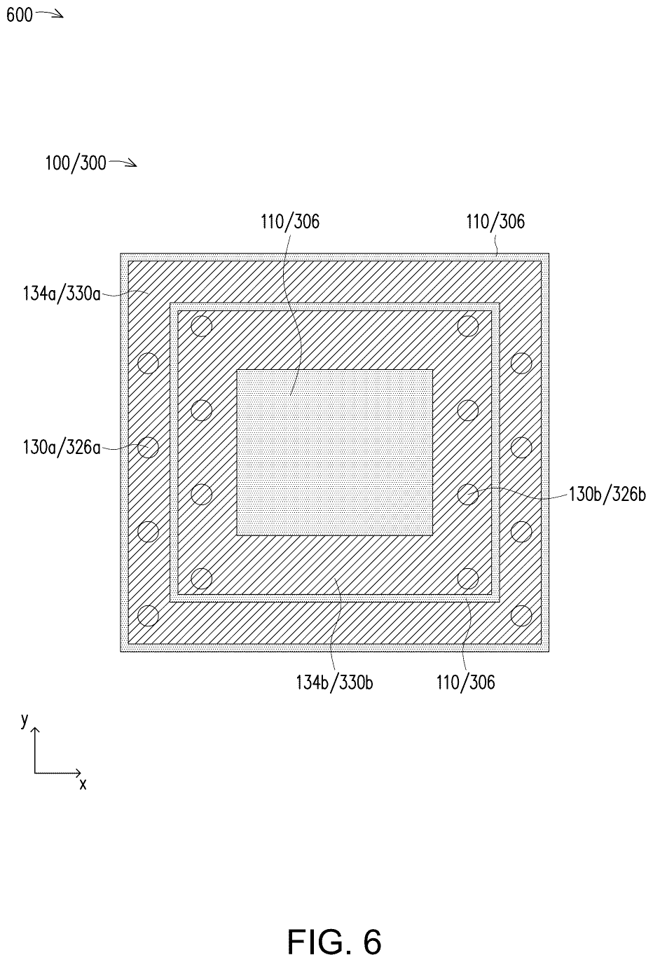

FIG. 6 is a diagram of an example implementation 600 of a semiconductor device 100 or 300 described herein. The example implementation 600 depicts a view from a first side (e.g., bottom side) of the semiconductor device 100 or 300 along the x-direction and the y-direction. Conductive routing layers 134a/330a for second electrodes 114/310 and an array of interconnect fill layers 130a/326a may be disposed under an insulator adhesion layer 110/306 and around a periphery of the semiconductor devices 100/300. Portions of the conductive routing layers 134a/330a are in physical contact with the interconnect fill layers 130a/326a. Conductive routing layers 134b/330b for first electrodes 112/308 and an array of interconnect fill layers 130b/326b may be disposed under an insulator adhesion layer 110/306, and inward of the conductive routing layers 134a/330a and of the interconnect fill layers 130a/326a in the x-direction. Portions of the conductive routing layers 134b/330b are in physical contact with the interconnect fill layers 130b/326b.

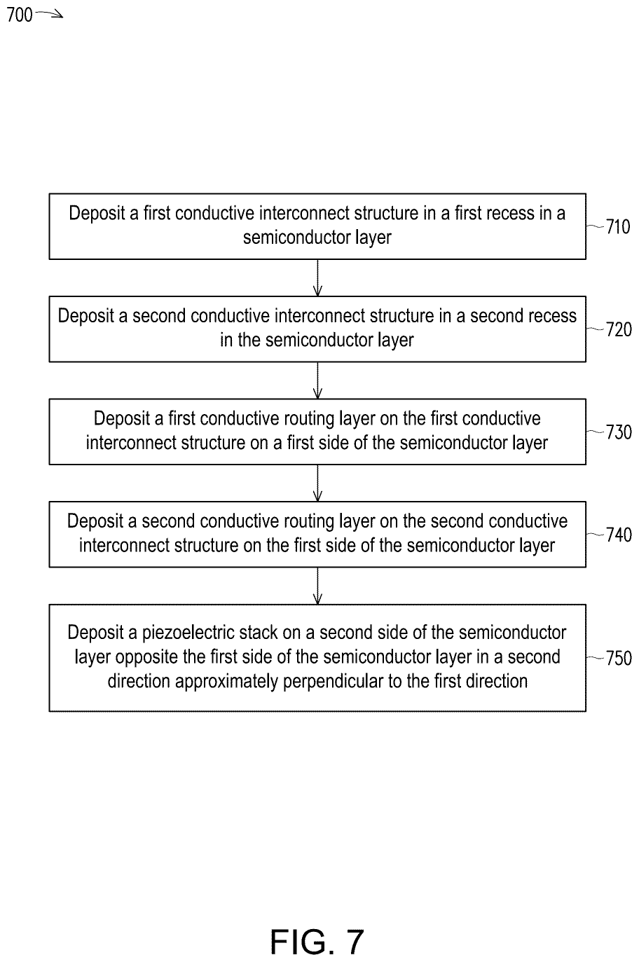

FIG. 7 is a flowchart of an example process 700 associated with forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include depositing a first conductive interconnect structure in a first recess in a semiconductor layer (block 710). For example, one or more semiconductor processing tools may be used to deposit a first conductive interconnect structure (e.g., an interconnect structure including a barrier layer 128, 324, and an interconnect fill layer 130a, 326a) in a first recess (e.g., a recess 206, 404) in a semiconductor layer (e.g., a semiconductor layer 102 or a substrate 302), as described herein.

As further shown in FIG. 7, process 700 may include depositing a second conductive interconnect structure in a second recess in the semiconductor layer (block 720). For example, one or more semiconductor processing tools may be used to deposit a second conductive interconnect structure (e.g., interconnect structure including a barrier layer 128, 324, and an interconnect fill layer 130b, 326b) in a second recess (e.g., a recess 206, 404) in the semiconductor layer, as described herein. In some implementations, the second conductive interconnect structure is adjacent to the first conductive interconnect structure in a first direction (e.g., x-direction).

As further shown in FIG. 7, process 700 may include depositing a first conductive routing layer on the first conductive interconnect structure on a first side of the semiconductor layer (block 730). For example, one or more semiconductor processing tools may be used to deposit a first conductive routing layer (e.g., conductive routing layer 134a, 330a) on the first conductive interconnect structure on a first side of the semiconductor layer, as described herein.

As further shown in FIG. 7, process 700 may include depositing a second conductive routing layer on the second conductive interconnect structure on the first side of the semiconductor layer (block 740). For example, one or more semiconductor processing tools may be used to deposit a second conductive routing layer (e.g., conductive routing layer 134b, 330b) on the second conductive interconnect structure on the first side of the semiconductor layer, as described herein.

As further shown in FIG. 7, process 700 may include depositing a piezoelectric stack on a second side of the semiconductor layer opposite the first side of the semiconductor layer in a second direction approximately perpendicular to the first direction (block 750). For example, one or more semiconductor processing tools may be used to deposit a piezoelectric stack on a second side of the semiconductor layer opposite the first side of the semiconductor layer in a second direction (e.g., z-direction) approximately perpendicular to the first direction, as described herein. In some implementations, the piezoelectric stack comprises a bottom electrode (e.g., first electrode 112, 308), a top electrode (e.g., second electrode 114, 310), and a piezoelectric layer (e.g., piezoelectric layer 116, 312) between the bottom electrode and top electrode. In some implementations, a portion of the top electrode is formed on a surface of the first conductive interconnect structure at the second side of the semiconductor layer. In some implementations, a portion of the bottom electrode is formed on a surface of the second conductive interconnect structure at the second side of the semiconductor layer.

Process 700 may include additional implementations, such as any single implementation or any combination of implementations described below and/or in connection with one or more other processes described elsewhere herein.

In a first implementation, process 700 includes etching the semiconductor layer to form the first recess and the second recess in the semiconductor layer, wherein depositing the first conductive interconnect structure and depositing the second conductive interconnect structure comprises depositing a barrier layer (e.g. barrier layer 128, 324) on side and bottom surfaces of the first recess and of the second recess, and depositing a conductive fill layer (e.g. conductive fill layer 130, 326) on the barrier layer in the first recess and in the second recess.

In a second implementation, alone or in combination with the first implementation, process 700 includes planarizing the conductive fill layer and the barrier layer on the first side of the semiconductor layer, and depositing a conductive adhesion layer (e.g., conductive adhesion layer 132, 328) on the planarized conductive fill layer and the planarized barrier layer prior to depositing the first conductive routing layer and the second conductive routing layer.

In a third implementation, alone or in combination with one or more of the first and second implementations, process 700 includes depositing an insulator layer (e.g., bottom insulator layer 124, 320) on and around the first conductive routing layer and the second conductive routing layer, depositing a passivation layer (e.g., passivation layer 136, 332) on the insulator layer, and etching portions of the passivation layer and the insulator layer to form openings (e.g., openings 138, 334) in the passivation layer and the insulator layer exposing portions of the first conductive routing layer and the second conductive routing layer.

In a fourth implementation, alone or in combination with one or more of the first through third implementations, process 700 includes depositing one or more insulator layers (e.g., base insulator layer 108, 304, and/or insulator adhesion layer 110, 306) on the second side of the semiconductor layer over the first conductive interconnect structure and over the second conductive interconnect structure, etching the one or more insulator layers to form a plurality of openings in the one or more insulator layers, wherein respective openings of the plurality of openings expose the surface of the first conductive interconnect structure and the surface of the second conductive interconnect structure, and depositing a conductive material layer (e.g., conductive layer 210) on the one or more insulator layers and in the plurality of openings to form the portion of the top electrode and the portion of the bottom electrode.

In a fifth implementation, alone or in combination with one or more of the first through fourth implementations, process 700 includes depositing the piezoelectric layer on the conductive material layer, and etching the piezoelectric layer and of the conductive material layer to remove portions of the piezoelectric layer and of the conductive material layer.

In a sixth implementation, alone or in combination with one or more of the first through fifth implementations, process 700 includes depositing a passivation layer (e.g., passivation layer 120, 316) on the piezoelectric layer and the conductive material layer, etching the passivation layer to remove portions of the passivation layer to expose the piezoelectric layer and the portion of the top electrode, and depositing a remaining portion of the top electrode on the passivation layer, on the piezoelectric layer, and on the portion of the top electrode.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, semiconductor devices are provided in which routing layers and piezoelectric structures are fabricated on opposite sides (e.g., a front side and a back side) of a substrate. The routing layers and electrodes of the piezoelectric structures are connected by interconnect structures which extend through the substrate between the opposite the sides of the substrate. The arrangement of the routing layers and piezoelectric structures enables the semiconductor devices to be manufactured without and/or with less planarization during fabrication than if the routing layers and piezoelectric structures were formed on the same side of the substrate. In addition, even if some planarization is performed on the routing layers during fabrication, the separation of the routing layers and piezoelectric structures by being on opposite sides of the substrate avoids and/or minimizes the effects that a built-up electric field in the routing layers may otherwise have on the structures. As a result, metal-based routing layers of the semiconductor device (e.g., copper-based and/or aluminum-based routing layers) may be fabricated with passivation layer coverage without causing unwanted current leakage, charge defects, and/or changes in switching charge in the piezoelectric structures, enabling increased reliability and performance of the piezoelectric structures to be achieved relative to if the routing layers and piezoelectric structures were formed on the same side of the substrate.

As described in greater detail above, some implementations described herein provide a semiconductor device. The semiconductor device includes a first electrode over a semiconductor layer. The semiconductor device includes a piezoelectric layer on a first portion of the first electrode. The semiconductor device includes a second electrode over the semiconductor layer, where a first portion of the second electrode is on the piezoelectric layer. The semiconductor device includes a first interconnect structure in the semiconductor layer, where a second portion of the second electrode is on the first interconnect structure, and where the first interconnect structure is on a first routing layer. The semiconductor device includes a second interconnect structure in the semiconductor layer, where a second portion of the first electrode is on the second interconnect structure, and where the second interconnect structure is on a second routing layer.

As described in greater detail above, some implementations described herein provide a method. The method includes depositing a first conductive interconnect structure in a first recess in a semiconductor layer. The method includes depositing a second conductive interconnect structure in a second recess in the semiconductor layer, where the second conductive interconnect structure is adjacent to the first conductive interconnect structure in a first direction. The method includes depositing a first conductive routing layer on the first conductive interconnect structure on a first side of the semiconductor layer. The method includes depositing a second conductive routing layer on the second conductive interconnect structure on the first side of the semiconductor layer. The method includes depositing a piezoelectric stack on a second side of the semiconductor layer opposite the first side of the semiconductor layer in a second direction approximately perpendicular to the first direction, where the piezoelectric stack comprises a bottom electrode, a top electrode, and a piezoelectric layer between the bottom electrode and top electrode. A portion of the top electrode is formed on a surface of the first conductive interconnect structure at the second side of the semiconductor layer. A portion of the bottom electrode is formed on a surface of the second conductive interconnect structure at the second side of the semiconductor layer.

As described in greater detail above, some implementations described herein provide a semiconductor device. The semiconductor device includes a semiconductor layer. The semiconductor device includes a plurality of interconnect structures disposed through the semiconductor layer. The semiconductor device includes a piezoelectric structure on the semiconductor layer, where the piezoelectric structure includes a bottom electrode, a ceramic layer on the bottom electrode, and a top electrode on the ceramic layer. The top electrode is in contact with a first interconnect structure of the plurality interconnect structures. The bottom electrode is in contact with a second interconnect structure of the plurality of interconnect structures.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first electrode over a semiconductor layer;
a piezoelectric layer on a first portion of the first electrode;
a second electrode over the semiconductor layer,
wherein a first portion of the second electrode is on the piezoelectric layer;
a first interconnect structure in the semiconductor layer,
wherein a second portion of the second electrode is on the first interconnect structure;
wherein the first interconnect structure is on a first routing layer; and
a second interconnect structure in the semiconductor layer,
wherein a second portion of the first electrode is on the second interconnect structure; and
wherein the second interconnect structure is on a second routing layer.

2. The semiconductor device of claim 1, wherein the first interconnect structure is laterally adjacent to the second interconnect structure.

3. The semiconductor device of claim 1, wherein the second portion of the first electrode is laterally adjacent to the second portion of the second electrode.

4. The semiconductor device of claim 1, wherein the first interconnect structure and the second interconnect structure extend through the semiconductor layer.

5. The semiconductor device of claim 1, further comprising an insulator layer under the semiconductor layer,
wherein the first routing layer and the second routing layer are in the insulator layer.

6. The semiconductor device of claim 5, further comprising a passivation layer under the insulator layer.

7. The semiconductor device of claim 1, further comprising a passivation layer over the second portion of the first electrode,
wherein a third portion of the second electrode is over the passivation layer.

8. The semiconductor device of claim 7, wherein the second portion of the second electrode is connected to the third portion of the second electrode through a break in the passivation layer.

9. The semiconductor device of claim 1, wherein part of the first portion of first electrode, part of the piezoelectric layer, and part of the first portion of the second electrode are over a cavity in the semiconductor layer.

10. A method, comprising:
depositing a first conductive interconnect structure in a first recess in a semiconductor layer;
depositing a second conductive interconnect structure in a second recess in the semiconductor layer,
wherein the second conductive interconnect structure is adjacent to the first conductive interconnect structure in a first direction;
depositing a first conductive routing layer on the first conductive interconnect structure on a first side of the semiconductor layer;
depositing a second conductive routing layer on the second conductive interconnect structure on the first side of the semiconductor layer; and
depositing a piezoelectric stack on a second side of the semiconductor layer opposite the first side of the semiconductor layer in a second direction approximately perpendicular to the first direction,
wherein the piezoelectric stack comprises a bottom electrode, a top electrode, and a piezoelectric layer between the bottom electrode and top electrode;
wherein a portion of the top electrode is formed on a surface of the first conductive interconnect structure at the second side of the semiconductor layer; and
wherein a portion of the bottom electrode is formed on a surface of the second conductive interconnect structure at the second side of the semiconductor layer.

11. The method of claim 10, further comprising:
etching the semiconductor layer to form the first recess and the second recess in the semiconductor layer,
wherein depositing the first conductive interconnect structure and depositing the second conductive interconnect structure comprises:
depositing a barrier layer on side and bottom surfaces of the first recess and of the second recess; and
depositing a conductive fill layer on the barrier layer in the first recess and in the second recess.

12. The method of claim 11, further comprising:
planarizing the conductive fill layer and the barrier layer on the first side of the semiconductor layer; and
depositing a conductive adhesion layer on the planarized conductive fill layer and the planarized barrier layer prior to depositing the first conductive routing layer and the second conductive routing layer.

13. The method of claim 10, further comprising:
depositing an insulator layer on and around the first conductive routing layer and the second conductive routing layer;
depositing a passivation layer on the insulator layer; and
etching portions of the passivation layer and the insulator layer to form openings in the passivation layer and the insulator layer exposing portions of the first conductive routing layer and the second conductive routing layer.

14. The method of claim 10, further comprising:
depositing one or more insulator layers on the second side of the semiconductor layer over the first conductive interconnect structure and over the second conductive interconnect structure;
etching the one or more insulator layers to form a plurality of openings in the one or more insulator layers,
wherein respective openings of the plurality of openings expose the surface of the first conductive interconnect structure and the surface of the second conductive interconnect structure; and
depositing a conductive material layer on the one or more insulator layers and in the plurality of openings to form the portion of the top electrode and the portion of the bottom electrode.

15. The method of claim 14, further comprising:
depositing the piezoelectric layer on the conductive material layer; and
etching the piezoelectric layer and of the conductive material layer to remove portions of the piezoelectric layer and of the conductive material layer.

16. The method of claim 15, further comprising:
depositing a passivation layer on the piezoelectric layer and the conductive material layer;
etching the passivation layer to remove portions of the passivation layer to expose the piezoelectric layer and the portion of the top electrode; and
depositing a remaining portion of the top electrode on the passivation layer, on the piezoelectric layer, and on the portion of the top electrode.

17. A semiconductor device, comprising:
a semiconductor layer;
a plurality of interconnect structures disposed through the semiconductor layer;
a piezoelectric structure on the semiconductor layer,
wherein the piezoelectric structure comprises:
a bottom electrode;
a ceramic layer on the bottom electrode; and
a top electrode on the ceramic layer;
wherein the top electrode is in contact with a first interconnect structure of the plurality of interconnect structures; and
wherein the bottom electrode is in contact with a second interconnect structure of the plurality of interconnect structures.

18. The semiconductor device of claim 17, wherein the ceramic layer comprises a piezoelectric material; and
wherein the ceramic layer is a switching layer of a ferroelectric random-access memory (FRAM) device.

19. The semiconductor device of claim 17, further comprising a cavity in the semiconductor layer,
wherein the cavity is laterally adjacent to the second interconnect structure;
wherein part of the piezoelectric structure is over the cavity; and
wherein the semiconductor device is one of an actuator, a sensor, or a harvester.

20. The semiconductor device of claim 17, further comprising:
a first metal routing layer under the first interconnect structure; and
a second metal routing layer under the second interconnect structure.
